(19) United States
(12) Patent Application Publication
(10) Pub. No.: US 2023/0038152 A1
(43) Pub. Date: Feb. 9, 2023

(54) SEMICONDUCTOR MEMORY DEVICE AND OPERATING METHOD THEREOF

(71) Applicant: SK hynix Inc., Icheon-si Gyeonggi-do (KR)

(72) Inventor: Hee Youl LEE, Icheon-si Gyeonggi-do (KR)

(73) Assignee: SK hynix Inc., Icheon-si Gyeonggi-do (KR)

(21) Appl. No.: 17/550,345

(22) Filed: Dec. 14, 2021

(30) Foreign Application Priority Data
Aug. 4, 2021 (KR) 10-2021-0102561

(51) Int. Cl. G11C 16/34; G11C 16/08; G11C 16/24; G11C 16/04; G11C 16/14

(52) U.S. Cl. CPC G11C 16/3459; G11C 16/08; G11C 16/24; G11C 16/0483; G11C 16/14

(57) ABSTRACT

A semiconductor memory device includes a memory block including plurality of string groups, a peripheral circuit, and control logic. The peripheral circuit performs a program operation on source select transistors included in the memory block. The control logic controls the program operation of the peripheral circuit. Each of the plurality of string groups includes at least one cell string, and the at least one cell string includes inner source select transistors located adjacent to memory cells and outer source select transistors located adjacent to a common source line. The control logic controls the peripheral circuit to perform program operations on the outer source select transistors and the inner source select transistors by an ISPP method. The control logic controls the peripheral circuit to perform a verify operation by dividing the inner source select transistors into at least two groups during the program operation of the inner source select transistors.

### CROSS-REFERENCE to RELATED APPLICATION

The present application claims priority under 35 U.S.C. § 119(a) to Korean patent application number 10-2021-0102561 filed on Aug. 4, 2021, in the Korean Intellectual Property Office, the entire disclosure of which is incorporated by reference herein.

### BACKGROUND

### 1. Technical Field

Various embodiments of the present teachings relate generally to an electronic device, and more particularly, to semiconductor memory device and an operating method thereof.

### 2. Related Art

A semiconductor memory device may have a two-dimensional structure in which strings are arranged in a horizontal direction to a semiconductor substrate, or a three-dimensional structure in which strings are arranged in a vertical direction to the semiconductor device. A three-dimensional memory device is devised to overcome the limited degree of integration in a two-dimensional memory device, and may include a plurality of memory cells vertically stacked on a semiconductor substrate.

### SUMMARY

Various embodiments are directed to a semiconductor memory device capable of improving a threshold voltage distribution of select transistors and an operating method thereof.

According to an embodiment of the present disclosure, a semiconductor memory device may include a memory block including a plurality of string groups, a peripheral circuit configured to perform a program operation on source select transistors included in the memory block, and control logic controlling the program operation of the peripheral circuit, wherein each of the plurality of string groups includes at least one cell string, and the at least one cell string includes inner source select transistors located adjacent to memory cells and outer source select transistors located adjacent to a common source line, wherein the control logic controls the peripheral circuit to perform a program operation on the outer source select transistors and a program operation on the inner source select transistors by applying a program voltage a plurality of times to an inner source select line coupled to the inner source select transistors, and wherein the control logic controls the peripheral circuit to perform a verify operation by dividing the inner source select transistors into at least two groups during the program operation of the inner source select transistors.

The plurality of string groups may include first, second, third, and fourth string groups, wherein an inner source select transistor in the first string group and an inner source select transistor in the second string group are commonly coupled to a first inner source select line, wherein an inner source select transistor in the third string group and an inner source select transistor in the fourth string group are commonly coupled to a second inner source select line, wherein an outer source select transistor in the first string group and an outer source select transistor in the second string group are commonly coupled to a first outer source select line, and wherein an outer source select transistor in the third string group and an outer source select transistor in the fourth string group are commonly coupled to a second outer source select line.

During the program operation of the outer source select transistors, the control logic may be configured to control the peripheral circuit to apply a turn-on voltage to first to fourth drain select lines coupled to the first to fourth string groups, respectively, and to apply a program pass voltage to the first and second inner source select lines and word lines coupled to the first to fourth string groups, and control the peripheral circuit to apply the program voltage to the first and second outer source select lines.

The control logic may control the peripheral circuit to apply the program voltage to the first and second outer source select lines a predetermined number of times.

During the program operation of the outer source select transistors, the control logic may be configured to control the peripheral circuit to apply a turn-on voltage to first to fourth drain select lines coupled to the first to fourth string groups, respectively, and to apply a program pass voltage to word lines coupled to the first to fourth string groups, and control the peripheral circuit to apply the program voltage to the first and second outer source select lines and the first and second inner source select lines.

The control logic may control the peripheral circuit to apply the program voltage to the first and second outer source select lines and the first and second inner source select lines a predetermined number of times.

The program operation of the inner source select transistors may include a plurality of program loops, and during at least one of the plurality of program loops, the control logic may be configured to set states of first to fourth drain select lines and first to fourth bit lines coupled to the first to fourth string groups, respectively, apply a program pass voltage to word lines coupled to the first to fourth string groups, apply a turn-off voltage to the first and second outer source select lines, apply the program voltage to the first and second inner source select lines, and perform the verify operation on the inner source select transistors included in the first to fourth string groups.

During the verify operation of the inner source select transistors included in the first to fourth string groups, the control logic may control the peripheral circuit to verify the inner source select transistors included in the first and third string groups, among the first to fourth string groups, and verify the inner source select transistors included in the second and fourth string groups, among the first to fourth string groups.

During the verify operation of the inner source select transistors included in the first to third string groups, the control logic may control the peripheral circuit to set a voltage of the common source line and a voltage of bit lines coupled to the first to fourth string groups, apply a turn-on voltage to the first and second outer source select lines, apply the turn-on voltage to drain select lines coupled to the first and third string groups and the turn-off voltage to drain select lines coupled to the second and fourth string groups, apply a verify pass voltage to the word lines, and apply a verify voltage to the first and second inner source select lines.

To set the voltage of the common source line and the voltage of the bit lines coupled to the first to fourth string groups, the control logic may control the peripheral circuit to apply a voltage of a 0 V to the common source line, apply a first voltage greater than 0 V to the bit lines coupled to the first to third string groups, and apply a voltage of 0 V to the bit lines coupled to the second and fourth string groups.

During the verify operation of the inner source select transistors included in the first to fourth string groups, the control logic may control the peripheral circuit to verify the inner source select transistors included in the first string group, among the first to fourth string groups, verify the inner source select transistors included in the second string group, among the first to fourth string groups, verify the inner source select transistors included in the third string group, among the first to fourth string groups, and verify the inner source select transistors included in the fourth string group, among the first to fourth string groups.

During the verify operation of the inner source select transistors included in the first string group, the control logic may control the peripheral circuit to set a voltage of the common source line and a voltage of bit lines coupled to the first to fourth string groups, apply a turn-on voltage to the first outer source select line and the turn-off voltage to the second outer source select line, apply the turn-on voltage to a drain select line coupled to the first string group and the turn-off voltage to drain select lines coupled to the second to fourth string groups, apply a verify pass voltage to the word lines, and apply a verify voltage to the first inner source select line and the turn-off voltage to the second inner source select line.

To set the states of the first to fourth drain select lines and the first to fourth bit lines coupled to the first to fourth string groups, respectively, the control logic may control the peripheral circuit to apply a program inhibition voltage to a bit line coupled to a string group verified completely in a previous program loop, apply a program permission voltage to a bit line coupled to a string group not verified completely in the previous program loop, and apply a turn-on voltage to drain select lines coupled to the first to fourth string groups.

To set the states of the first to fourth drain select lines and the first to fourth bit lines coupled to the first to fourth string groups, respectively, the control logic may control the peripheral circuit to apply a program permission voltage to bit lines coupled to the first to fourth string groups, apply a turn-on voltage to a drain select line coupled to a string group not verified completely in a previous program loop, and apply the turn-off voltage to a bit line coupled to a string group completely verified in the previous program loop.

The control logic may control the peripheral circuit to perform a soft erase operation on the outer source select transistors included in the first to fourth string groups in response to verify completion of the inner source select transistors of all string groups.

According to an embodiment of the present disclosure, a method of operating a semiconductor memory device performing a program operation on a source select transistor of a memory block including a plurality of string groups, the plurality of string groups each including at least one cell string, the at least one cell string including inner source select transistors located adjacent to memory cells and outer source select transistors located adjacent to a common source line, may include performing a program operation on the outer source select transistors, and performing a program operation on the inner source select transistors by applying a plurality of program voltages to gates of the inner source select transistors a plurality of times, wherein the performing of the program operation on the inner source select transistors comprises performing a verify operation by dividing the inner source select transistors into at least two groups.

The plurality of string groups may include first, second, third, and fourth string groups, wherein an inner source select transistor in the first string group and an inner source select transistor in the second string group are commonly coupled to a first inner source select line, wherein an inner source select transistor in the third string group and an inner source select transistor in the fourth string group are commonly coupled to a second inner source select line, wherein an outer source select transistor in the first string group and an outer source select transistor in the second string group are commonly coupled to a first outer source select line, wherein an outer source select transistor in the third string group and an outer source select transistor in the fourth string group are commonly coupled to a second outer source select line, and wherein the performing of the program operation on the outer source select transistors comprises applying a turn-on voltage to first to fourth drain select lines coupled to the first to fourth string groups, respectively, and applying a program pass voltage to the first and second inner source select lines and word lines coupled to the first to fourth string groups, and applying a program voltage to the first and second outer source select lines.

The applying of the program voltage to the first and second outer source select lines may include applying the program voltage to the first and second source select lines a predetermined number of times.

The plurality of string groups may include first, second, third, and fourth string groups, wherein an inner source select transistor in the first string group and an inner source select transistor in the second string group are commonly coupled to a first inner source select line, wherein an inner source select transistor in the third string group and an inner source select transistor in the fourth string group are commonly coupled to a second inner source select line, wherein an outer source select transistor in the first string group and an outer source select transistor in the second string group are commonly coupled to a first outer source select line, wherein an outer source select transistor in the third string group and an outer source select transistor in the fourth string group are commonly coupled to a second outer source select line, and wherein the performing of the program operation on the outer source select transistors comprises: applying a turn-on voltage to first to fourth drain select lines coupled to the first to fourth string groups, respectively, and applying a program pass voltage to word lines coupled to the first to fourth string groups, and applying a program voltage to the first and second outer source select lines and the first and second inner source select lines.

The applying of the program voltage to the first and second inner source select lines and the first and second outer source select lines may include applying the program voltage to the first and second inner source select lines and the first and second outer source select lines a predetermined number of times.

The performing of the program operation on the inner source select transistors may include a plurality of program loops, and one of the plurality of program loops comprises: setting states of first to fourth drain select lines and first to fourth bit lines coupled to the first to fourth string groups, respectively, applying a program pass voltage to word lines coupled to the first to fourth string groups, applying a turn-off voltage to the first and second outer source select lines, applying a program voltage to the first and second inner source select lines, and performing the verify operation on the inner source select transistors included in the first to fourth string groups.

The performing of the verify operation on the inner source select transistors included in the first to fourth string groups may include: verifying the inner source select transistors included in the first and third string groups, among the first to fourth string groups, and verifying the inner source select transistors included in the second and fourth string groups, among the first to fourth string groups.

The performing of the verify operation on the inner source select transistors included in the first to third string groups may include: setting a voltage of the common source line and a voltage of bit lines coupled to the first to fourth string groups, applying a turn-on voltage to the first and second outer source select lines, applying the turn-on voltage to drain select lines coupled to the first and third string groups and the turn-off voltage to drain select lines coupled to the second and fourth string groups, applying a verify pass voltage to the word lines, and applying a verify voltage to the first and second inner source select lines.

The setting of the voltage of the common source line and the voltage of the bit lines coupled to the first to fourth string groups may include applying a voltage of a 0 V to the common source line, applying a first voltage greater than 0 V to the bit lines coupled to the first to third string groups, and applying a voltage of 0 V to the bit lines coupled to the second and fourth string groups.

The performing of the verify operation on the inner source select transistors included in the first to fourth string groups may include verifying the inner source select transistors included in the first string group, among the first to fourth string groups, verifying the inner source select transistors included in the second string group, among the first to fourth string groups, verifying the inner source select transistors included in the third string group, among the first to fourth string groups, and verifying the inner source select transistors included in the fourth string group, among the first to fourth string groups.

The performing of the verify operation of the inner source select transistors included in the first string group may include setting a voltage of the common source line and a voltage of bit lines coupled to the first to fourth string groups, applying a turn-on voltage to the first outer source select line and the turn-off voltage to the second outer source select line, applying the turn-on voltage to a drain select line coupled to the first string group and the turn-off voltage to drain select lines coupled to the second to fourth string groups, applying a verify pass voltage to the word lines, and applying a verify voltage to the first inner source select line and the turn-off voltage to the second inner source select line.

The setting of the states of the first to fourth drain select lines and the first to fourth bit lines coupled to the first to fourth string groups, respectively, may include applying a program inhibition voltage to a bit line coupled to a string group verified completely in a previous program loop, applying a program permission voltage to a bit line coupled to a string group not verified completely in the previous program loop, and applying a turn-on voltage to drain select lines coupled to the first to fourth string groups.

The setting of the states of the first to fourth drain select lines and the first to fourth bit lines coupled to the first to fourth string groups, respectively, may include applying a program permission voltage to bit lines coupled to the first to fourth string groups, applying a turn-on voltage to a drain select line coupled to a string group not verified completely in a previous program loop, and applying the turn-off voltage to a bit line coupled to a string group verified completely in the previous program loop.

The method may further include performing a soft erase operation on the outer source select transistors included in the first to fourth string groups when verification of the inner source select transistors of all string groups is completed.

### BRIEF DESCRIPTION OF THE DRAWINGS

FIG. 1 is a block diagram illustrating a semiconductor memory device according to an embodiment of the present disclosure;

FIG. 2 is a diagram illustrating an embodiment of a memory cell array of FIG. 1;

FIG. 3 is a circuit diagram illustrating one of memory blocks shown in FIG. 2;

FIG. 4 is a circuit diagram illustrating another embodiment of one of the memory blocks shown in FIG. 2;

FIG. 5 is a diagram illustrating one example of string groups forming a memory block;

FIG. 6A is a detailed circuit diagram illustrating a first string group among string groups shown in FIG. 5;

FIG. 6B is a circuit diagram illustrating a portion of cell strings included in first and second string groups;

FIG. 7 is a diagram illustrating another example of string groups forming a memory block;

FIGS. 8A and 8B are circuit diagrams illustrating a portion of cell strings included in first to fourth string groups;

FIGS. 9A, 9B, and 9C are circuit diagrams illustrating a portion of cell strings included in first to fourth string groups;

FIG. 10 is a flowchart illustrating a method of operating a semiconductor memory device according to an embodiment of the present disclosure;

FIG. 11A is a flowchart illustrating an embodiment of step S110 of FIG. 10;

FIG. 11B is a flowchart illustrating another embodiment of step S110 of FIG. 10;

FIG. 12 is a diagram illustrating step S110 of FIG. 10;

FIG. 13 is a flowchart illustrating an embodiment of step S130 shown in FIG. 10.

FIG. 14 is a diagram illustrating steps S310 to S340 of FIG. 13;

FIG. 15 is a diagram illustrating step S370 of FIG. 13;

FIG. 16 is a flowchart illustrating an embodiment of step S350 of FIG. 13;

FIG. 17 is a flowchart illustrating an embodiment of step S410 of FIG. 16;

FIG. 18A is a diagram illustrating step S410 of FIG. 16;

FIG. 18B is a diagram illustrating step S430 of FIG. 16;

FIG. 19 is a flowchart illustrating another embodiment of step S370 shown in FIG. 13;

FIG. 20 is a flowchart illustrating an embodiment of step S610 shown in FIG. 19;

FIG. 21A is a diagram illustrating step S610 of FIG. 19;

FIG. 21B is a diagram illustrating step S630 of FIG. 19;

FIG. 22 is a flowchart illustrating an embodiment of step S310 shown in FIG. 13;

FIG. 23 is a diagram illustrating steps S810 to S830 of FIG. 22;

FIG. 24 is a flowchart illustrating another embodiment of step S310 shown in FIG. 13;

FIG. 25 is a diagram illustrating steps S840 to S860 of FIG. 24;

FIG. 26 is a circuit diagram illustrating another embodiment of a portion of cell strings included in first to fourth string groups;

FIG. 27 is a block diagram illustrating an embodiment (1000) of a memory system including a semiconductor memory device 100 of FIG. 1;

FIG. 28 is a block diagram illustrating an application example of a memory system shown in FIG. 27; and

FIG. 29 is a block diagram illustrating a computing system including a memory system described with reference to FIG. 28.

### DETAILED DESCRIPTION

Specific structural or functional descriptions of examples of embodiments in accordance with concepts which are disclosed in this specification are illustrated only to describe the examples of embodiments in accordance with the concepts and the examples of embodiments in accordance with the concepts may be carried out by various forms but the descriptions are not limited to the examples of embodiments described in this specification.

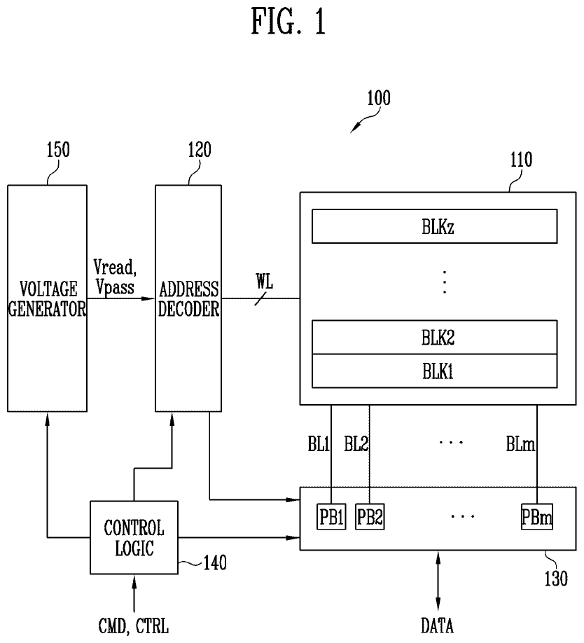

FIG. 1 is a block diagram illustrating a semiconductor memory device 100 according to an embodiment of the present disclosure.

Referring to FIG. 1, the semiconductor memory device 100 may include a memory cell array 110, an address decoder 120, a read and write circuit 130, control logic 140, and a voltage generator 150.

The memory cell array 110 may include a plurality of memory blocks BLK1 to BLKz. The plurality of memory blocks BLK1 to BLKz may be coupled to the address decoder 120 through word lines WL. The plurality of memory blocks BLK1 to BLKz may be coupled to the read and write circuit 130 through bit lines BL1 to BLm. Each of the plurality of memory blocks BLK1 to BLKz may include a plurality of memory cells. According to an embodiment, the plurality of memory cells may be non-volatile memory cells, which have a vertical channel structure. The memory cell array 110 may have a two-dimensional structure. According to an embodiment, the memory cell array 110 may have a three-dimensional structure. Each of the plurality of memory cells included in the memory cell array may store at least 1-bit data. According to an embodiment, each of the plurality of memory cells included in the memory cell array 110 may be a single-level cell (SLC) which stores 1-bit data. According to another embodiment, each of the plurality of memory cells included in the memory cell array 110 may be a multi-level cell (MLC) which stores 2-bit data. According to another embodiment, each of the plurality of memory cells included in the memory cell array 110 may be a triple-level cell (TLC) which stores three bits of data. According to another embodiment, each of the plurality of memory cells included in the memory cell array 110 may be a quad-level cell (QLC) which stores four bits of data. According to an embodiment, each of the plurality of memory cells included in the memory cell array 110 may store five or more bits of data.

The address decoder 120, the read and write circuit 130, the control logic 140, and the voltage generator 150 may operate as peripheral circuits configured to drive the memory cell array 110. The address decoder 120 may be coupled to the memory cell array 110 through the word lines WL. The address decoder 120 may be controlled by the control logic 140. The address decoder 120 may receive an address through an input/output buffer (not illustrated) in the semiconductor memory device 100.

The address decoder 120 may be configured to decode a block address of the received address. The address decoder 120 may select at least one memory block according to the decoded block address. In addition, during a read voltage applying operation in a read operation, the address decoder 120 may apply a read voltage Vread generated by the voltage generator 150 to a selected word line of a selected memory block and may apply a pass voltage Vpass to unselected word lines. In addition, during a program verify operation, the address decoder 120 may apply a verify voltage generated by the voltage generator 150 to the selected word line of the selected memory block, and may apply the pass voltage Vpass to unselected word lines.

The address decoder 120 may be configured to decode a column address of the received address. The address decoder 120 may transfer the decoded column address to the read and write circuit 130.

A read operation and a program operation of the semiconductor memory device 100 may be performed in units of pages. An address received at the request of a read operation and a program operation may include a block address, a row address, and a column address. The address decoder 120 may select one memory block and one word line in response to the block address and the row address. The column address may be decoded by the address decoder 120 and provided to the read and write circuit 130.

The address decoder 120 may include a block decoder, a row decoder, a column decoder, and an address buffer.

The read and write circuit 130 may include a plurality of page buffers PB1 to PBm. The read and write circuit 130 may operate as a read circuit during a read operation of the memory cell array 110 and a write circuit during a write operation thereof. The page buffers PB1 to PBm may be coupled to the memory cell array 110 through the bit lines BL1 to BLm. The page buffers PB1 to PBm may continuously supply a sensing current to bit lines coupled to memory cells in order to sense threshold voltages of memory cells and sense changes in amount of current caused by program states of memory cells corresponding thereto through a sensing node to latch sensing data during a read operation and a program verify operation. The read and write circuit 130 may operate in response to page buffer control signals output from the control logic 140.

The read and write circuit 130 may sense data of a memory cell, temporarily store the read data, and output data DATA to the input/output buffer (not illustrated) of the semiconductor memory device 100 during a read operation. According to an embodiment, the read and write circuit 130 may include a column selector in addition to the page buffers (or page registers).

The control logic 140 may be coupled to the address decoder 120, the read and write circuit 130, and the voltage generator 150. The control logic 140 may receive a command CMD and a control signal CTRL through the input/output buffer (not illustrated) of the semiconductor memory device 100. The control logic 140 may be configured to control general operations of the semiconductor memory device 100 in response to the control signal CTRL. In addition, the control logic 140 may output a control signal to control sensing node precharge potential levels of the page buffers PB1 to PBm. The control logic 140 may control the read and write circuit 130 to perform a read operation of the memory cell array 110. The control logic 140 may be implemented as hardware, software, or a combination of hardware and software. For example, the control logic 140 may be a control logic circuit operating in accordance with an algorithm and/or a processor executing control logic code.

The voltage generator 150 may generate the read voltage Vread and the pass voltage Vpass in response to a control signal output from the control logic 140 during a read operation. The voltage generator 150 may include a plurality of pumping capacitors receiving an internal power voltage to generate a plurality of voltages having various voltage levels, and may generate a plurality of voltages by selectively activating the plurality of pumping capacitors in response to control of the control logic 140.

The address decoder 120, the read and write circuit 130, and the voltage generator 150 may function as a ‘peripheral circuit’ configured to perform a read operation, a write operation, and an erase operation on the memory cell array 110. The control logic 140 may control the peripheral circuit to perform a read operation, a write operation, and an erase operation on the memory cell array 110.

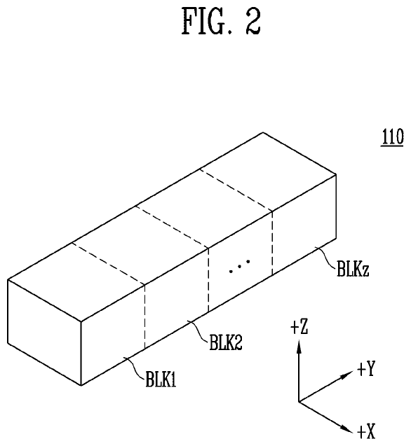

FIG. 2 is a diagram illustrating an embodiment of the memory cell array 110 of FIG. 1.

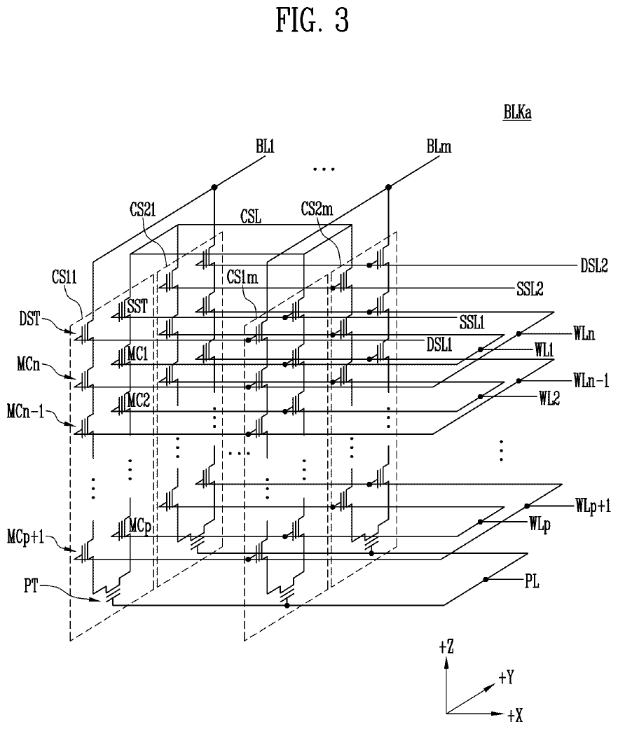

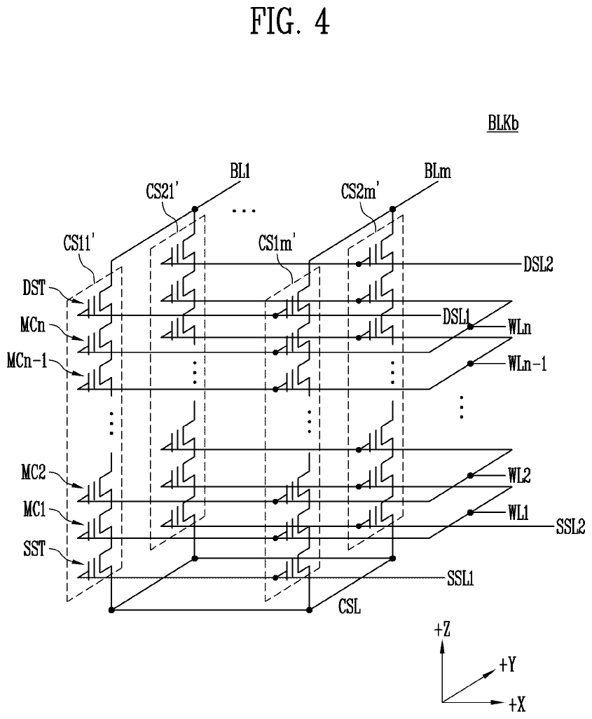

Referring to FIG. 2, the memory cell array 110 may include the plurality of memory blocks BLK1 to BLKz. Each of the memory blocks BLK1 to BLKz may have a three-dimensional structure. Each memory block may include a plurality of memory cells that are stacked over a substrate. The plurality of memory cells may be arranged in +X direction, +Y direction, and +Z direction. The structure of each memory block will be described in detail below with reference to FIGS. 3 and 4.

FIG. 3 is a circuit diagram illustrating one (BLKa) of the memory blocks BLK1 to BLKz shown in FIG. 2.

Referring to FIG. 3, the memory block BLKa may include a plurality of cell strings CS11 to CS1m and CS21 to CS2m. According to an embodiment, each of the plurality of cell strings CS11 to CS1m and CS21 to CS2m may be formed in a ‘U’ shape. In the memory block BLKa, ‘m’ cell strings may be arranged in a row direction (i.e., +X direction). FIG. 3 illustrates two cell strings arranged in a column direction (i.e., +Y direction). However, it is understood that three or more cell strings may be arranged in the column direction.

Each of the cell strings CS11 to CS1m and CS21 to CS2m may include at least one source select transistor SST, first to nth memory cells MC1 to MCn, a pipe transistor PT, and at least one drain select transistor DST.

Each of the select transistors SST and DST and each of the memory cells MC1 to MCn may have similar structures to each other. According to an embodiment, each of the select transistors SST and DST and the memory cells MC1 to MCn may include a channel layer, a tunneling insulating layer, a charge storage layer, and a blocking insulating layer. According to an embodiment, a pillar for providing a channel layer may be provided in each cell string. According to an embodiment, a pillar for providing at least one of the channel layer, the tunneling insulating layer, the charge storage layer, and the blocking insulating layer may be provided to each cell string.

The source select transistor SST of each cell string may be coupled between a common source line CSL and first to pth memory cells MC1 to MCp.

According to an embodiment, source select transistors of cell strings arranged in the same row may be coupled to a source select line extending in a row direction, and source select transistors of cell strings arranged in different rows may be coupled to different source select lines. In FIG. 3, source select transistors of the cell strings CS11 to CS1m in the first row may be coupled to a first source select line SSL1. Source select transistors of the cell strings CS21 to CS2m in the second row may be coupled to a second source select line SSL2.

According to another embodiment, the source select transistors of the cell strings CS11 to CS1m and CS21 to CS2m may be coupled in common to one source select line.

The first to nth memory cells MC1 to MCn of each cell string may be coupled between the source select transistor SST and the drain select transistor DST.

The first to nth memory cells MC1 to MCn may be divided into the first to pth memory cells MC1 to MCp and (p+1)th to nth memory cells MCp+1 to MCn. The first to pth memory cells MC1 to MCp may be sequentially arranged in a reverse direction to the +Z direction and may be coupled in series between the source select transistor SST and the pipe transistor PT. The (p+1)th to nth memory cells MCp+1 to MCn may be sequentially arranged in the +Z direction and may be coupled in series between the pipe transistor PT and the drain select transistor DST. The first to pth memory cells MC1 to MCp and the (p+1)th to nth memory cells MCp+1 to MCn may be coupled through the pipe transistor PT. Gates of the first to nth memory cells MC1 to MCn of each cell string may be coupled to first to nth word lines WL1 to WLn, respectively.

A gate of the pipe transistor PT of each cell string may be coupled to a pipe line PL.

The drain select transistor DST of each cell string may be coupled between a corresponding bit line and the memory cells MCp+1 to MCn. Cell strings arranged in the row direction may be coupled to a drain select line extending in the row direction. The drain select transistors of the cell strings CS11 to CS1m in the first row may be coupled to a first drain select line DSL1. The drain select transistors of the cell strings CS21 to CS2m in the second row may be coupled to a second drain select line DSL2.

Cell strings arranged in the column direction may be coupled to a bit line extending in the column direction. In FIG. 3, the cell strings CS11 and CS21 in the first column may be coupled to the first bit line BL1. The strings CS1m and CS2m in the mth column be coupled to the mth bit line BLm.

Memory cells coupled to the same word line arranged in cell strings arranged in the row direction may form a single page. For example, memory cells coupled to the first word line WL1 in the cell strings CS11 to CS1m in the first row may constitute a single page. Memory cells coupled to the first word line WL1 in the cell strings CS21 to CS2m in the second row may constitute another page. When one of the drain select lines DSL1 and DSL2 is selected, cell strings arranged in one row direction may be selected. When one of the first to nth word lines WL1 to WLn is selected, one page may be selected from the selected cell strings.

According to another embodiment, even bit lines and odd bit lines may replace the first to mth bit lines BL1 to BLm. In addition, even cell strings of the cell strings CS11 to CS1m or CS21 to CS2m arranged in the row direction may be coupled to the even bit lines, respectively, and odd cell strings of the cell strings CS11 to CS1m or CS21 to CS2m arranged in the row direction may be coupled to the odd bit lines, respectively.

According to an embodiment, at least one of the first to nth memory cells MC1 to MCn may serve as a dummy memory cell. For example, one or more dummy memory cells may be provided to reduce an electric field between the source select transistor SST and the non-dummy memory cells among the memory cells MC1 to MCp. Alternatively, one or more dummy memory cells may be provided to reduce an electric field between the drain select transistor DST and the non-dummy memory cells among the memory cells MCp+1 to MCn. When more dummy memory cells are provided, the operational reliability of the memory block BLKa may be improved, whereas the size of the memory block BLKa may be increased. On the other hand, when the number of dummy memory cells decreases, the size of the memory block BLKa may be reduced, and the operational reliability of the memory block BLKa may be reduced.

In order to efficiently control one or more dummy memory cells, each of the dummy memory cells may have a required threshold voltage. Before or after an erase operation on the memory block BLKa, program operations may be performed on a portion or entirety of the dummy memory cells. When an erase operation is performed after a program operation is performed, the dummy memory cells may have required threshold voltages by controlling a voltage applied to dummy word lines coupled to the dummy memory cells.

FIG. 4 is a circuit diagram illustrating another embodiment (BLKb) of one of the memory blocks BLK1 to BLKz shown in FIG. 2.

Referring to FIG. 4, the memory block BLKb may include a plurality of cell strings CS11′ to CS1m′ and CS21′ to CS2m′. Each of the plurality of cell strings CS11′ to CS1m′ and CS21′ to CS2m′ may extend in the +Z direction. Each of the plurality of cell strings CS11′ to CS1m′ and CS21′ to CS2m′ may include at least one source select transistor SST, the first to nth memory cells MC1 to MCn, and at least one drain select transistor DST which are stacked on a substrate (not shown) under the memory block BLKb.

The source select transistor SST of each cell string may be coupled between the common source line CSL and the memory cells MC1 to MCn. Source select transistors of cell strings arranged in the same row may be coupled to the same source select line. Source select transistors of the cell strings CS11′ to CS1m′ arranged in the first row may be coupled to the first source select line SSL1. Source select transistors of the cell strings CS21′ to CS2m′ arranged in the second row may be coupled to the second source select line SSL2. According to another embodiment, the source select transistors of the cell strings CS11′ to CS1m′ and CS21′ to CS2m′ may be coupled in common to one source select line.

The first to nth memory cells MC1 to MCn of each cell string may be coupled in series between the source select transistor SST and the drain select transistor DST. Gates of the first to nth memory cells MC1 to MCn may be coupled to the first to nth word lines WL1 to WLn, respectively.

The drain select transistor DST of each cell string may be coupled between the corresponding bit line and the memory cells MC1 to MCn. Drain select transistors of cell strings arranged in a row direction may be coupled to a drain select line extending in the row direction. The drain select transistors of the cell strings CS11′ to CS1m′ in the first row may be coupled to the first drain select line DSL1. The drain select transistors of the cell strings CS21′ to CS2m′ in the second row may be coupled to the second drain select line DSL2.

As a result, the memory block BLKb shown in FIG. 4 may have a similar circuit structure to the memory block BLKa shown in FIG. 3 except that the pipe transistor PT is removed from each cell string of the memory block BLKb.

According to another embodiment, even bit lines and odd bit lines may replace the first to mth bit lines BL1 to BLm. In addition, even cell strings of the cell strings CS11′ to CS1m′ or CS21′ to CS2m′ arranged in the row direction may be coupled to the even bit lines, respectively, and odd cell strings of the cell strings CS11′ to CS1m′ or CS21′ to CS2m′ arranged in the row direction may be coupled to the odd bit lines, respectively.

According to an embodiment, at least one of the first to nth memory cells MC1 to MCn may serve as a dummy memory cell. For example, one or more dummy memory cells may be provided to reduce an electric field between the source select transistor SST and the non-dummy memory cells among the first to nth memory cells MC1 to MCn. Alternatively, one or more dummy memory cells may be provided to reduce an electric field between the drain select transistor DST and the non-dummy memory cells among the memory cells MC1 to MCn. When more dummy memory cells are provided, the operational reliability of the memory block BLKb may be improved, whereas the size of the memory block BLKb may be increased. On the other hand, when the number of dummy memory cells decreases, the size of the memory block BLKb may be reduced, and the operational reliability of the memory block BLKb may be reduced.

In order to efficiently control one or more dummy memory cells, each of the dummy memory cells may have a required threshold voltage. Before or after an erase operation on the memory block BLKb, program operations may be performed on a portion or entirety of the dummy memory cells. When an erase operation is performed after a program operation is performed, the dummy memory cells may have required threshold voltages by controlling a voltage applied to dummy word lines coupled to the dummy memory cells.

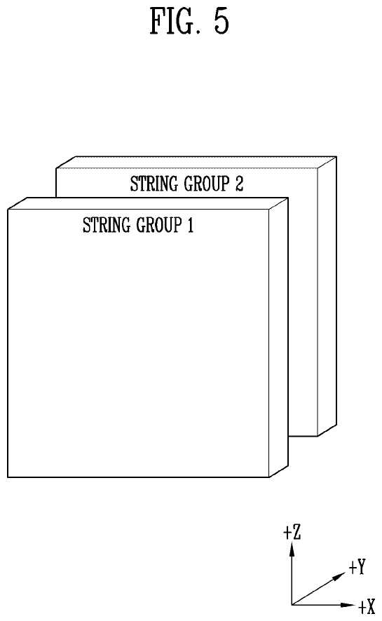

FIG. 5 is a diagram illustrating one example of string groups forming a memory block.

FIG. 5 shows string groups STRING GROUP 1 and STRING GROUP 2 included in the memory block BLKa or BLKb as shown in FIG. 3 or 4. According to an embodiment, referring to FIG. 3, the string group included in the memory block BLKa may be defined as cell strings that share a drain select line or a source select line. For example, in FIG. 3, the cell strings CS11 to CS1m that share the first drain select line DSL1 and the first source select line SSL1 may constitute the first string group STRING GROUP 1. The cell strings CS21 to CS2m that share the second drain select line DSL2 and the second source select line SSL2 may form the second string group STRING GROUP 2.

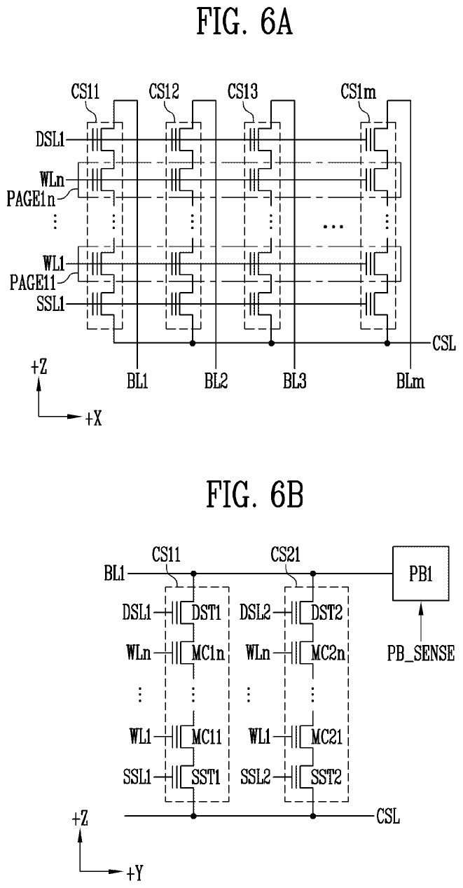

In another example, in FIG. 4, the cell strings CS11′ to CS1m′ that share the first drain select line DSL1 and the first source select line SSL1 may form the first string group STRING GROUP 1. The cell strings CS21′ to CS2m′ that share the second drain select line DSL2 and the second source select line SSL2 may constitute the second string group STRING GROUP 2. A memory block may include the two string groups STRING GROUP 1 and STRING GROUP 2 arranged in the +Y direction. Each of the string groups STRING GROUP 1 and STRING GROUP 2 may include cell strings arranged in the row direction (i.e., +X direction). Each of the string groups STRING GROUP 1 and STRING GROUP 2 may include pages arranged in a string direction (i.e., +Z direction). A detailed configuration of each string group will be described below with reference to FIGS. 6A and 6B.

FIG. 6A is a detailed circuit diagram illustrating the first string group STRING GROUP 1 among the string groups shown in FIG. 5. The second string group STRING GROUP 2 may be configured in the same manner as the first string group STRING GROUP 1. Thus, a detailed circuit diagram of the second string group will be omitted.

Referring to FIG. 6A, the first string group STRING GROUP 1 may include the cell strings CS11 to CS1m that share the first drain select line DSL1 and the first source select line SSL1. In other words, the cell strings CS11 to CS1m included in the first string group STRING GROUP 1 may be coupled in common to the first drain select line DSL1 and the first source select line SSL1. In the first string group STRING GROUP 1, the cell strings CS11 to CS1m may be arranged in the +X direction. The cell strings CS11 to CS1m may be coupled to the bit lines BL1 to BLm corresponding thereto.

The first string group STRING GROUP 1 may include pages PAGE11 to PAGE1n that are arranged in the +Z direction. Each of the pages PAGE11 to PAGE1n may be a set of memory cells that are coupled to each of the word lines WL1 to WLn corresponding thereto.

Though not shown in FIG. 6A, the second string group STRING GROUP 2 may include the cell strings CS21 to CS2m arranged in the +X direction. The second string group STRING GROUP 2 may include pages PAGE21 to PAGE2n that are arranged in the +Z direction.

FIG. 6B is a circuit diagram illustrating a portion of cell strings included in first and second string groups.

FIG. 6B shows the cell string CS11 included in the string group STRING GROUP 1 and the cell string CS21 included in the second string group STRING GROUP 2. FIG. 6B may be a circuit diagram which illustrates the memory block, shown in FIG. 5, in the +X direction. Therefore, the cell strings CS12 to CS1m included in the first string group STRING GROUP 1 and the cell strings CS22 to CS2m included in the second string group STRING GROUP 2 are not shown in FIG. 6B.

The cell string CS11 of the first string group STRING GROUP 1 may include memory cells MC11 to MC1n that are coupled between a first drain select transistor DST1 and a first source select transistor SST1. The cell string CS21 of the second string group STRING GROUP 2 may include memory cells MC21 to MC2n that are coupled between a second drain select transistor DST2 and a second source select transistor SST2.

The cell string CS11 included in the first string group STRING GROUP 1 and the cell string CS21 included in the second string group STRING GROUP 2 may be coupled in common to the bit line BL1. The page buffer PB1 may be commonly coupled to the bit line BL1. In other words, the cell string CS11 included in the first string group STRING GROUP 1 and the cell string CS21 included in the second string group STRING GROUP 2 may share the page buffer PB1. The page buffer PB1 may operate based on a PB_SENSE signal. Though not shown in FIG. 6B, the page buffer PB1 may operate based on other control signals in addition to the PB_SENSE signal.

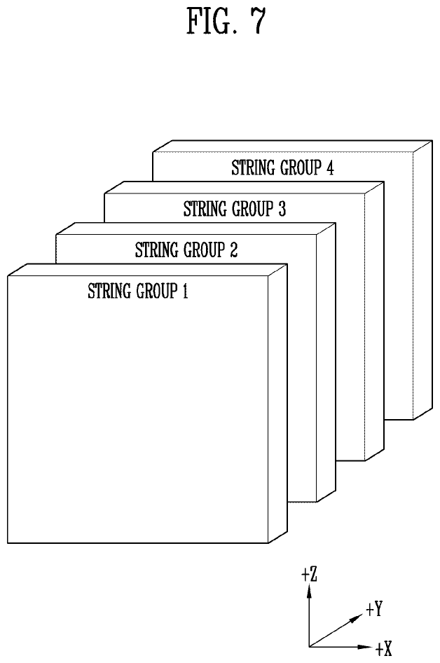

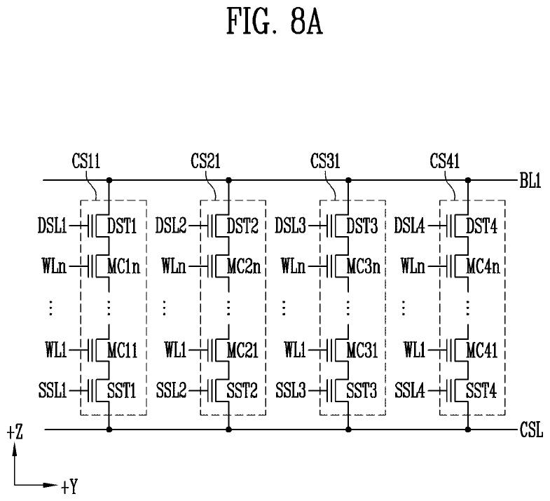

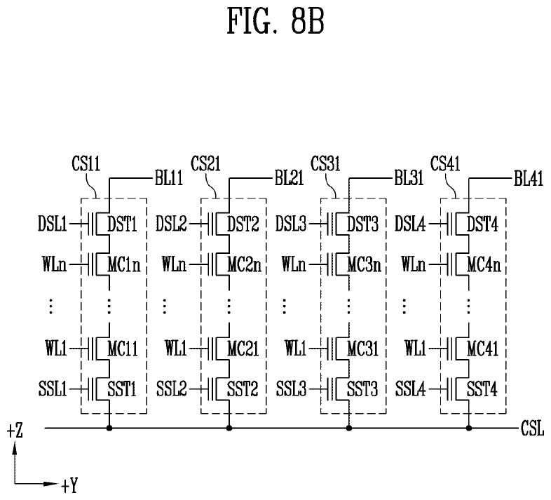

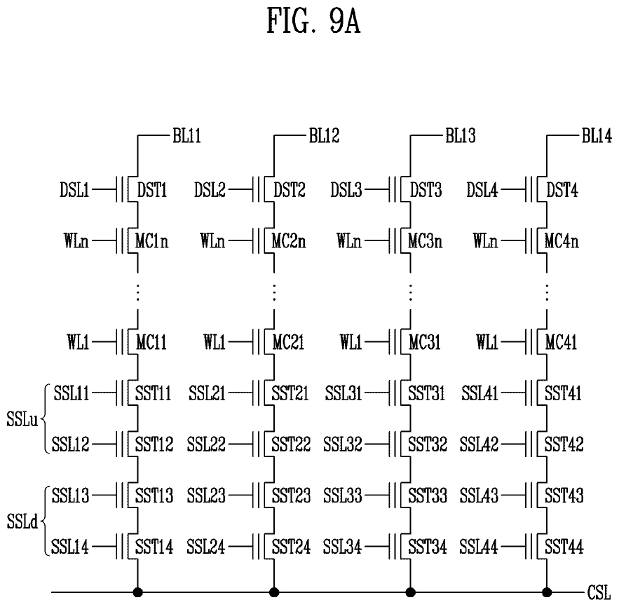

FIG. 7 is a diagram illustrating another example of string groups forming a memory block. FIGS. 8A and 8B are circuit diagrams illustrating a portion of cell strings included in first to fourth (i.e., first, second, third, and fourth) string groups.

Referring to FIG. 7, a memory block may include four string groups STRING GROUP 1 to STRING GROUP 4. As described above with reference to FIG. 4, a string group included in a memory block may be defined as cell strings that share a drain select line or a source select line. Although the memory block as shown in FIG. 5 includes two string groups, the memory block may be configured to include four string groups as shown in FIG. 7.

FIG. 8A shows the cell string CS11 included in the first string group STRING GROUP 1, the cell string CS21 included in the second string group STRING GROUP 2, the cell string CS31 included in the third string group STRING GROUP 3, and the cell string CS41 included in the fourth string group STRING GROUP 4. FIG. 8A may be a circuit diagram which illustrates the memory block, shown in FIG. 7, in the +X direction.

The cell string CS11 of the first string group STRING GROUP 1 may include memory the memory cells MC11 to MC1nthat are coupled between the first drain select transistor DST1 and the first source select transistor SST1. The cell string CS21 of the second string group STRING GROUP 2 may include the memory cells MC21 to MC2n that are coupled between the second drain select transistor DST2 and the second source select transistor SST2. The cell string CS31 of the third string group STRING GROUP 3 may include memory cells MC31 to MC3n that are coupled between a third drain select transistor DST3 and a third source select transistor SST3. The cell string CS41 of the fourth string group STRING GROUP 4 may include memory cells MC41 to MC4n that are coupled between a third drain select transistor DST4 and a fourth source select transistor SST4. As described above with reference to FIG. 6B, the cell strings CS11 to CS41 included in the first to fourth string groups STRING GROUP 1 to STRING GROUP 4, respectively, may be coupled in common to the bit line BL1. A page buffer may be coupled in common to the bit line BL1. In other words, the cell strings CS11 to CS41 included in the first to fourth string groups STRING GROUP 1 to STRING GROUP 4 may share the page buffer PB1.

FIG. 8B illustrates a cell string structure which is similar to that shown in FIG. 8A. In the cell string structure as shown in FIG. 8A, the cell strings CS11 to CS41 included in the first to fourth string groups STRING GROUP 1 to STRING GROUP 4 may be coupled in common to the bit line BL1. In the cell string structure as shown in FIG. 8B, the cell strings CS11, CS21, CS31, and CS41 included in the first, second, third, and fourth string groups STRING GROUP 1, 2, 3, and 4 may be coupled to the corresponding bit lines BL11, BL12, BL13, and BL14, respectively. Page buffers may be coupled to the bit lines BL11, BL12, BL13, and BL14. As a result, in the cell string structure as shown in FIG. 8B, the cell strings CS11, CS21, CS31, and CS41 included in the first, second, third, and fourth string groups STRING GROUP 1, 2, 3, and 4 might not share a page buffer.

The memory block including two string groups has been described above with reference to FIGS. 5 and 6. However, the memory block including four string groups as shown in FIGS. 8A and 8B may also be possible.

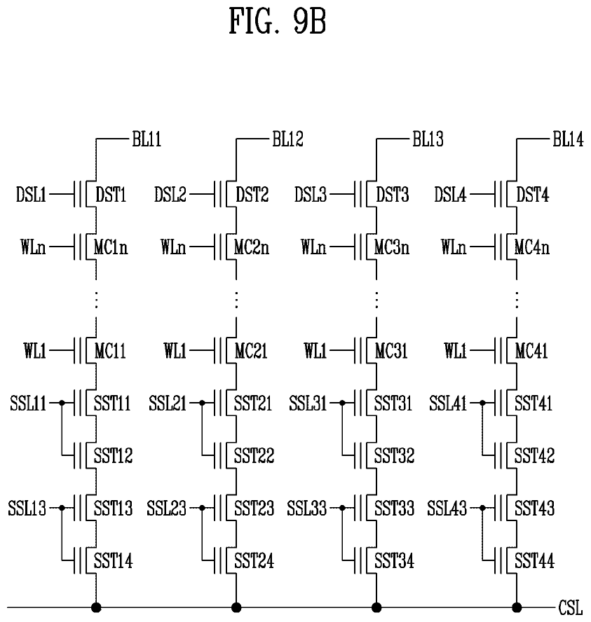

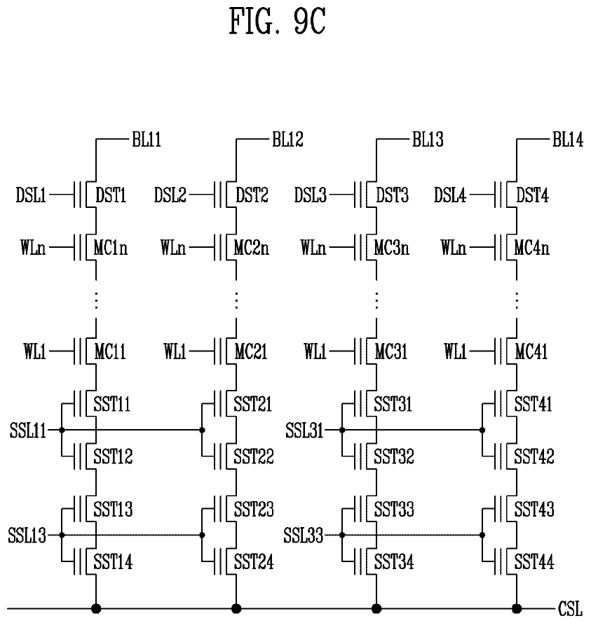

FIGS. 9A, 9B, and 9C are circuit diagrams illustrating a portion of cell strings included in first to fourth string groups.

Referring to FIG. 9A, each cell string may include a plurality of source select transistors. In the circuit diagram shown in FIG. 9A, a first cell string may include first to fourth source select transistors SST11 to SST14, and a second cell string may include first to fourth source select transistors SST21 to SST24. A third cell string may include first to fourth source select transistors SST31 to SST34, and a fourth cell string may include first to fourth source select transistors SST41 to SST44.

The first to fourth source select transistors SST11 to SST14 of the first cell string may be coupled to source select lines SSL11 to SSL14 corresponding thereto. The first to fourth source select transistors SST21 to SST24 of the second cell string may be coupled to source select lines SSL21 to SSL24 corresponding thereto. The first to fourth source select transistors SST31 to SST34 of the third cell string may be coupled to source select lines SSL31 to SSL34 corresponding thereto. The first to fourth source select transistors SST41 to SST44 of the fourth cell string may be coupled to source select lines SSL41 to SSL44 corresponding thereto.

In the present specification, source select transistors located adjacent to memory cells among a plurality of source select transistors are referred to as “inner source select transistors.” Source select transistors located adjacent to the common source line CSL, among the plurality of source select transistors, are referred to as “outer source select transistors.” For example, inner source select transistors among the first to fourth source select transistors SST11 to SST14 of the first cell string may be the first and second source select transistors SST11 and SST12, and outer source select transistors thereof may be the third and fourth source select transistors SST13 and SST14. In the same manner, inner source select transistors among the first to fourth source select transistors SST21 to SST24 of the second cell string may be the first and second source select transistors SST21 and SST22, and outer source select transistors thereof may be the third and fourth source select transistors SST23 and SST24. In addition, inner source select transistors among the first to fourth source select transistors SST31 to SST34 of the third cell string may be the first and second source select transistors SST31 and SST32, and outer source select transistors thereof may be the third and fourth source select transistors SST33 and SST34. Lastly, inner source select transistors among the first to fourth source select transistors SST41 to SST44 of the fourth cell string may be the first and second source select transistors SST41 and SST42, and outer source select transistors thereof may be the third and fourth source select transistors SST43 and SST44.

In the present specification, a source select line coupled to the inner source select transistor is referred to as an “inner source select line SSLu” and a source select line coupled to an outer source select transistor is referred to as an “outer source select line SSLd”. As shown in FIG. 9A, the first source select lines SSL11, SSL21, SSL31, and SSL41 and the second source select lines SSL12, SSL22, SSL32, and SSL42 coupled to the first to fourth cell strings may be inner source select lines SSLu, and the third source select lines SSL13, SSL23, SSL33, and SSL43 and the fourth source select lines SSL14, SSL24, SSL34, and SSL44 may be outer source select lines SSLd.

As shown in FIG. 9A, a plurality of source select transistors may be coupled to individual source select lines which are differentiated from each other. However, in another embodiment, a plurality of source select transistors may share source select lines. A description will be made with reference to FIGS. 9B and 9C.

Referring to FIG. 9B, source select transistors included in each cell string may share a source select line and be coupled to each other. For example, the first and second source select transistors SST11 and SST12 of the first cell string may be coupled to the first source select line SSL11, and the third and fourth source select transistors SST13 and SST14 may be coupled to the third source select line SSL13. The first and second source select transistors SST21 and SST22 of the second cell string may be coupled to the first source select line SSL21, and the third and fourth source select transistors SST23 and SST24 may be coupled to the third source select line SSL23. The first and second source select transistors SST31 and SST32 of the third cell string may be coupled to the first source select line SSL31, and the third and fourth source select transistors SST33 and SST34 may be coupled to the third source select line SSL33. The first and second source select transistors SST41 and SST42 of the fourth cell string may be coupled to the first source select line SSL41, and the third and fourth source select transistors SST43 and SST44 may be coupled to the third source select line SSL43.

According to an embodiment shown in FIG. 9B, a plurality of source select transistors may be controlled through fewer source select lines than those of the embodiment of FIG. 9A.

Referring to FIG. 9C, source select transistors included in different cell strings may share a source select line and be coupled to each other. For example, the first and second source select transistors SST11 and SST12 of the first cell string and the first and second source select transistors SST21 and SST22 of the second cell string may be commonly coupled to the first source select line SSL11. In addition, the third and fourth source select transistors SST13 and SST14 of the first cell string and the third and fourth source select transistors SST23 and SST24 of the second cell string may be commonly coupled to the third source select line SSL13.

In the same manner, the first and second source select transistors SST31 and SST32 of the third cell string and the first and second source select transistors SST41 and SST42 of the fourth cell string may be commonly coupled to the first source select line SSL31. In addition, the third and fourth source select transistors SST33 and SST34 of the third cell string and the third and fourth source select transistors SST43 and SST44 of the fourth cell string may be commonly coupled to the third source select line SSL33.

According to an embodiment shown in FIG. 9C, a plurality of source select transistors may be controlled through fewer source select lines than those of the embodiment of FIG. 9B. The present disclosure will be described below based on the memory cell array structure shown in FIG. 9C.

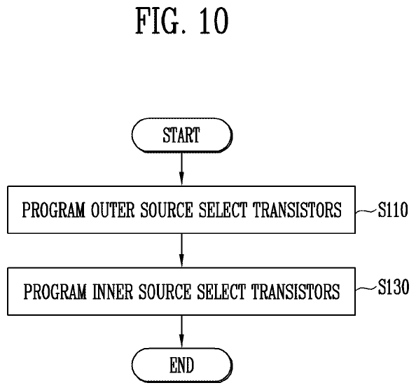

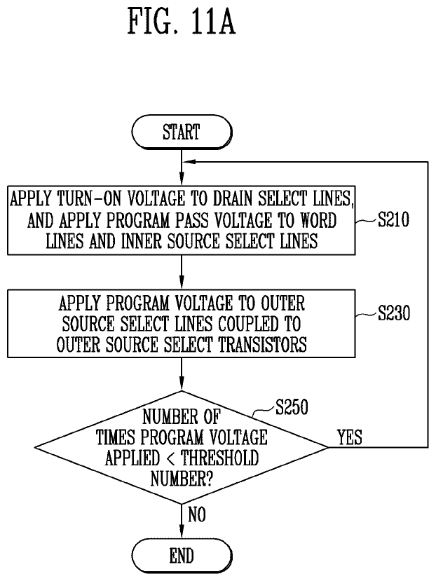

FIG. 10 is a flowchart illustrating a method of operating a semiconductor memory device according to an embodiment of the present disclosure.

According to an embodiment, a semiconductor memory device may program a source select transistor. Although source select transistors are not memory cells which store data, these source select transistors may have the same structure as memory cells coupled to word lines. In order for the semiconductor memory device to operate normally, threshold voltages of the source select transistors may be controlled so as to be in a predictable range. A semiconductor memory device according to an embodiment of the present disclosure may control threshold voltages of source select transistors by performing a program operation on the source select transistors. More specifically, the semiconductor memory device according to an embodiment may program a plurality of source select transistors by dividing the source select transistors.

Referring to FIG. 10, by a method of operating a semiconductor memory device according to an embodiment, a plurality of source select transistors included in each cell string may be programmed. More specifically, a method of operating a semiconductor memory device according to an embodiment may include programming outer source select transistors (S110) and programming inner source select transistors (S130).

At step S110, the outer source select transistor may be programmed without a verify operation. The outer source select transistors may be programmed by applying a program voltage to the outer source select lines SSLd a predetermined number of times. According to an embodiment, at step S110, the outer source select transistors and the inner source select transistors may be programmed at the same time. The outer source select transistors and the inner source select transistors may be programmed without a verify operation.

At step S130, a program operation may be performed on the inner source select transistor. Contrary to step S110, at step S130, the program operation may be performed together with a verify operation on the inner source select transistors. According to an embodiment, the program operation at step S130 may be performed using an Incremental Step Pulse Programming (ISPP) method. According to the ISPP method, memory cells may be programmed while a program voltage is gradually increased. A source select transistor may have the same structure as a memory cell although not being the memory cell. Thus, the source select transistor may be programmed using the ISPP method. Step S130 may include a plurality of program loops. As the program loops are repeatedly performed, the program voltage applied to the inner source select lines SSLu coupled to the inner source select transistors may be increased gradually. In another embodiment, the program operation at step S130 may be performed by repetitively applying a program voltage with a single level to gates of the inner source select transistors. Although the program loops are repeated, the program voltage applied to the inner source select lines SSLu coupled to the inner source select transistors may have a constant voltage level.

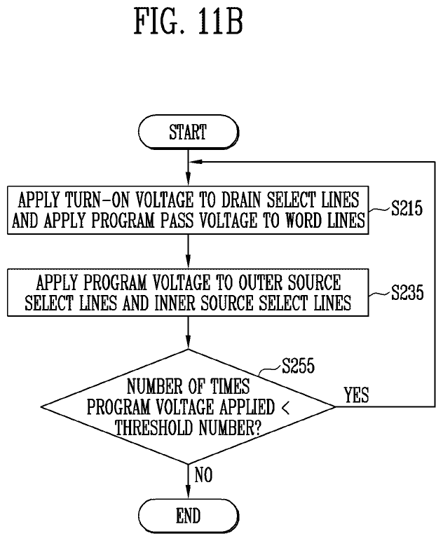

FIG. 11A is a flowchart illustrating an embodiment of step S110 of FIG. 10.

Referring to FIG. 11A, step S110 of programming the outer source select transistors may include applying a turn-on voltage V_{ON} to drain select lines and applying a program pass voltage V_{PS1} to word lines and inner source select lines (S210), and applying a program voltage V_{PGM} to the outer source select lines SSLd coupled to the outer source select transistors (S230). Accordingly, threshold voltages of the outer source select transistors may be increased.

According to an embodiment, the program voltage V_{PGM} may be applied one time to the outer source select lines SSLd coupled to the outer source select transistors. According to another embodiment, the program voltage V_{PGM} may be repetitively applied to the outer source select lines SSLd a predetermined threshold number of times. At step S250, it may be determined whether the number of times the program voltage V_{PGM} is applied to the outer source select lines SSLd is less than a threshold number. When the number of times the program voltage V_{PGM} is applied is less than the threshold number (S250: YES), steps S210 and S230 may be repeated. When the number of times the program voltage applied reaches the threshold number (S250: NO), the program operation of the outer source select transistors may be terminated.

FIG. 11B is a flowchart illustrating another embodiment of step S110 of FIG. 10.

Referring to FIG. 11B, step S110 of programming the outer source select transistors may include applying the turn-on voltage V_{ON} to drain select lines and applying the program pass voltage V_{PS1} to word lines (S215) and applying the program voltage V_{PGM} to the outer source select lines SSLd and the inner source select lines SSLu (S235). Therefore, threshold voltages of the outer source select transistors and the inner source select transistors may be increased.

According to an embodiment, the program voltage V_{PGM} may be applied one time to the inner and outer source select lines SSLd and SSLu. According to another embodiment, the program voltage V_{PGM} may be repetitively applied to the inner and outer source select lines SSLu and SSLd a predetermined threshold number of times. At step S255, it may be determined whether the number of times the program voltage V_{PGM} is applied to the inner and outer source select lines SSLu and SSLd is less than the threshold number. When the number of times the program voltage V_{PGM} is applied is less than the threshold number (S255: YES), steps S215 and S235 may be repeated. When the number of times the program voltage V_{PGM} applied reaches the threshold number (S255: NO), the program operation of the outer source select transistors may be terminated.

In the embodiment of FIG. 11A when compared against the embodiment of FIG. 11B, a program operation may be performed on only the outer source select transistors at step S110. On the other hand, at step S110, in the embodiment of FIG. 11B, a program operation may be performed on the outer source select transistors and the inner source select transistors at the same time. Therefore, according to the embodiment of FIG. 11B, at step S130 after step S110, a time taken to program the inner source select transistors may be reduced. As a result, according to the embodiment of FIG. 11B, a program speed of the source select transistors may be improved.

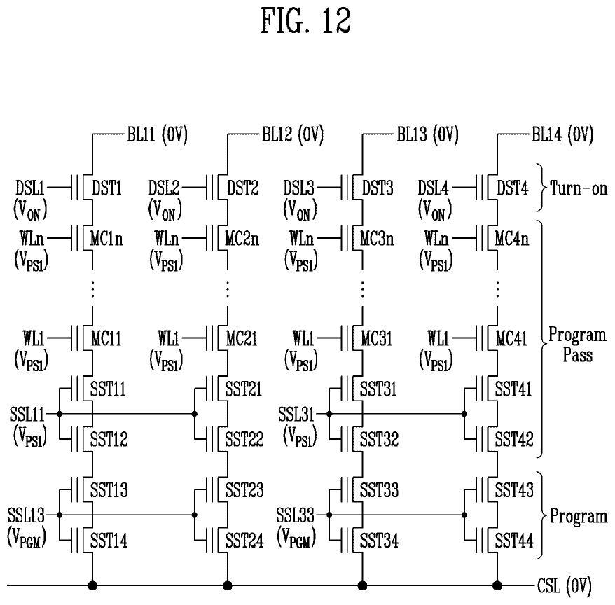

FIG. 12 is a diagram illustrating step S110 of FIG. 10.

Referring to FIG. 12, a program permission voltage, i.e., a voltage of 0 V may be applied to the bit lines BL11, BL12, BL13, and BL14, and a voltage of 0 V may be applied to the common source line CSL. The turn-on voltage V_{ON} may be applied to drain select lines DSL1 to DSL4, and the program pass voltage V_{PS1} may be applied to the word lines WL1 to WLn and the inner source select lines SSL11 and SSL31 at step S210. Therefore, the drain select transistors DST1 to DST4 may be turned on, and the memory cells MC11 to MC1n, MC21 to MC2n, MC31 to MC3n, and MC41 to MC4n and the inner source select transistors SST11, SST12, SST21, SST22, SST31, SST32, SST41, and SST42 may have a program pass status.

The program voltage V_{PGM} may be applied to the outer source select lines SSL13 and SSL33 coupled to the outer source select transistors SST13, SST14, SST23, SST24, SST33, SST34, SST43, and SST44. Accordingly, threshold voltages of the outer source select transistors SST13, SST14, SST23, SST24, SST33, SST34, SST43, and SST44 may be increased.

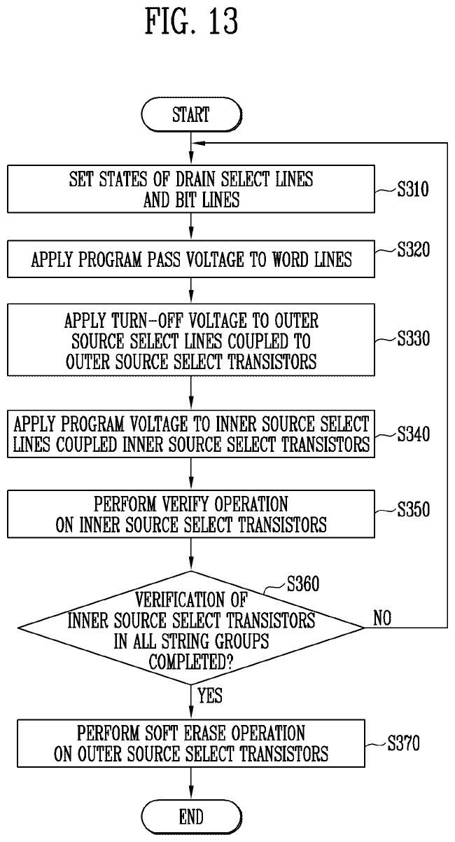

FIG. 13 is a flowchart illustrating an embodiment of step S130 shown in FIG. 10.

Referring to FIG. 13, step S130 of programming the inner source select transistors by the ISPP method may include setting states of drain select lines and bit lines (S310), applying a program pass voltage to word lines (S320), applying a turn-off voltage to outer source select lines coupled to outer source select transistors (S330), applying a program voltage to inner source select lines coupled to the inner source select transistors (S340), and performing a verify operation on the inner source select transistors (S350). Steps S310 to S350 may form a single program loop for programming the inner source select transistors.

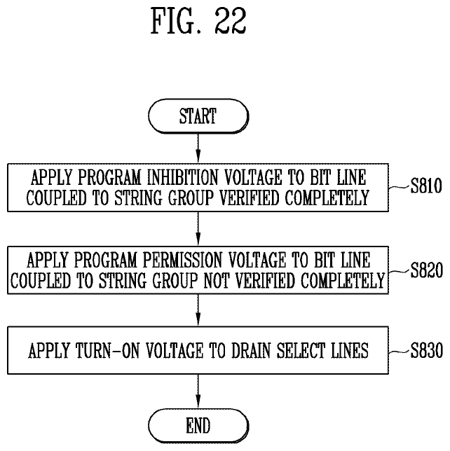

At step S310, states of the drain select lines and the bit lines may be set. According to a verify result of the previous program loop, inner source select transistors included in a string group which is not completely verified may be set to a program permission state, and inner source select transistors included in a string group which is completely verified may be set to a program inhibition state. By setting the states of the drain select lines and the bit lines, a program permission state and a program inhibition state of a plurality of inner source select lines may be set. Step S310 will be described in more detail with reference to FIGS. 22 to 25.

At step S320, memory cells may be in a program pass state as a program pass voltage is applied to word lines. By applying a turn-off voltage to outer source select lines at step S330, the common source line CSL may be electrically separated from inner source select transistors.

Subsequently, at step S340, threshold voltages of the inner source select transistors may be increased by applying the program voltage V_{PGM} to the inner source select lines. A verify operation of the inner source select transistors may then be performed at step S350.

According to an embodiment, the verify operation of the inner source select transistors may be performed at one time. For example, the verify operation of the inner source select transistors may be performed by applying a verify voltage to the inner source select lines at the same time. Threshold voltages of all source select transistors may be increased in a subsequent program loop even when verification of only a few inner source select transistors among the entirety of the inner source select transistors fails. The increase in the threshold voltages may result in a wider range of distribution of the threshold voltages. As a result, operation reliability of the semiconductor memory device may be reduced.

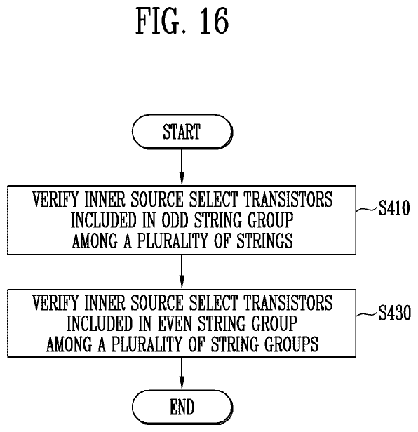

According to an embodiment of the present disclosure, a verify operation of the inner source select transistors may be performed by dividing the transistors into at least two groups. Thus, the threshold voltage of the group of the completely verified inner source select transistors might not be increased in a subsequent program loop, and threshold voltage distribution of the inner source select transistors may be narrowed. As a result, operation reliability of the semiconductor memory device may be improved. Embodiments of step S350 will be described below in more detail with reference to FIGS. 16 to 21.

At step S360, it may be determined whether verification of the inner source select transistors in all string groups is completed. When the verification of the inner source select transistors of all string groups is not completed (S360: NO), steps S310 to S350 may be repeated. When the verification of the inner source select transistors in all string groups is completed (S360: YES), program of the inner source select transistors may be terminated. According to an embodiment, when the verification of the inner source select transistors in all string groups is completed (S360: YES), a soft erase operation may be performed on the outer source select transistors at step S370. Step S370 may be optional; thus, step S370 may be skipped in some embodiments.

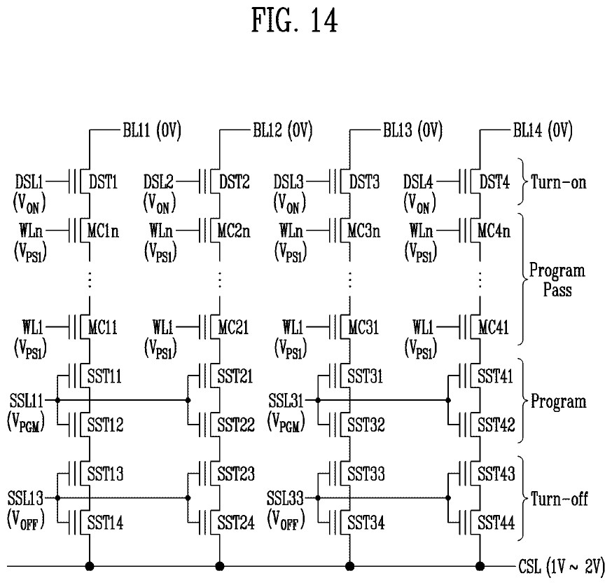

FIG. 14 is a diagram illustrating steps S310 to S340 of FIG. 13.

Referring to FIG. 14, it may be necessary to increase threshold voltages of all inner source select transistors at the beginning of the program operation of the inner source select transistors. A program permission voltage, i.e., a voltage of 0 V may be applied to the first to fourth bit lines BL11 to BL14, and the turn-on voltage V_{ON} may be applied to the first to fourth drain select lines DSL1 to DSL4 at step S310. Therefore, the first to fourth drain select transistors DST1 to DST4 may be turned on. The program pass voltage V_{PS1} may be applied to the word lines WL1 to WLn coupled to the memory cells at step S320, and a turn-off voltage V_{OFF} may be applied to the outer source select lines SSL13 and SSL33 at step S330. As the outer source select transistors SST13, SST14, SST23, SST24, SST33, SST34, SST43, and SST44 are turned off, a channel region of the inner source select transistors SST11, SST12, SST21, SST22, SST31, SST32, SST41, and SST42 may be electrically separated from the common source line CSL. For example, a voltage ranging from 1 V to 2 V may be applied to the common source line CSL.

Subsequently, the program voltage V_{PGM} may be applied to the inner source select lines SSL11 and SSL31 at step S340, and threshold voltages of the inner source select transistors SST11, SST12, SST21, SST22, SST31, SST32, SST41, and SST42 may be increased.

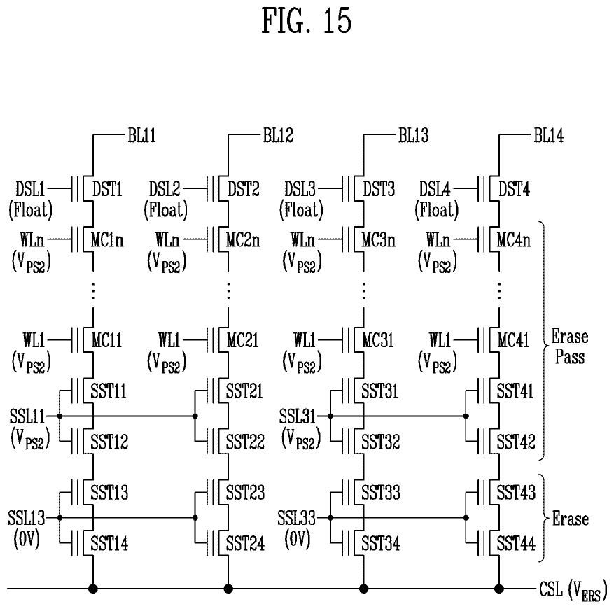

FIG. 15 is a diagram illustrating step S370 of FIG. 13.

Referring to FIG. 15, the first to fourth drain select lines DSL1 to DSL4 may be floated. However, a turn-off voltage may be applied to the first to fourth drain select lines DSL1 to DSL4. An erase pass voltage V_{PS2} may be applied to the word lines WL1 to WLn and the inner source select lines SSL11 and SSL31. The erase pass voltage V_{PS2} may be a voltage for causing the coupled memory cells or transistors to be in an erase pass state, and may be greater than an erase permission voltage. For example, the erase pass voltage V_{PS2} may be a voltage of 6 V or more.

Thereafter, the erase permission voltage may be applied to the outer source select lines SSL13 and SSL33. The erase permission voltage may be a voltage which causes the coupled memory cells or the transistors to be in an erase permission state, and may be, for example, 0 V.

Subsequently, an erase voltage V_{ERS} may be applied to the common source line CSL. Accordingly, threshold voltages of the outer source select transistors SST13, SST14, SST23, SST24, SST33, SST34, SST43, and SST44 in the erase permission state may be reduced. By setting the erase voltage V_{ERS} to a slightly low voltage, the outer source select transistors SST13, SST14, SST23, SST24, SST33, SST34, SST43, and SST44 may be soft erased.

FIG. 16 is a flowchart illustrating an embodiment of step S350 shown in FIG. 13.

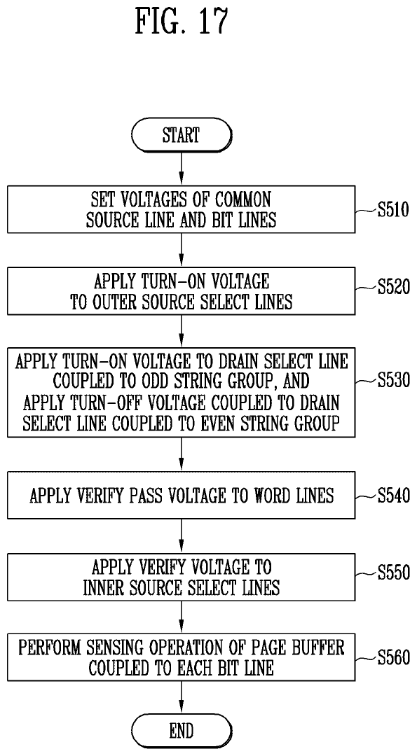

Referring to FIG. 16, in association with an operating method according to an embodiment of the present disclosure, step S350 of performing the verify operation on the inner source select transistors may include verifying inner source select transistors included in an odd string group, among a plurality of string groups (S410), and verifying inner source select transistors included in an even string group among the plurality of string groups (S430). FIG. 16 illustrates an embodiment in which the inner source select transistors included in the even string group are verified after the inner source select transistors included in the odd string group are verified. However, the present disclosure is not limited thereto. For example, after the inner source select transistors included in the even string group are verified, the inner source select transistors included in the odd string group may be verified. Hereinafter, step S410 of verifying the inner source select transistors included in the odd string group will be described below in more details with reference to FIG. 17.

FIG. 17 is a flowchart illustrating an embodiment of step S410 shown in FIG. 16.

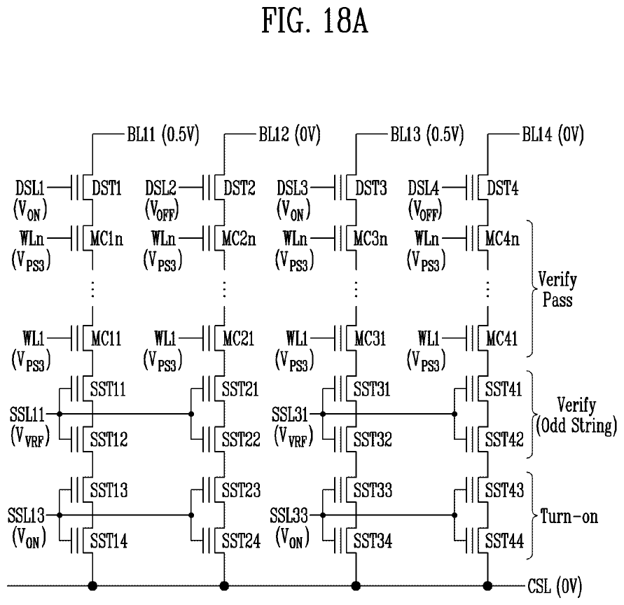

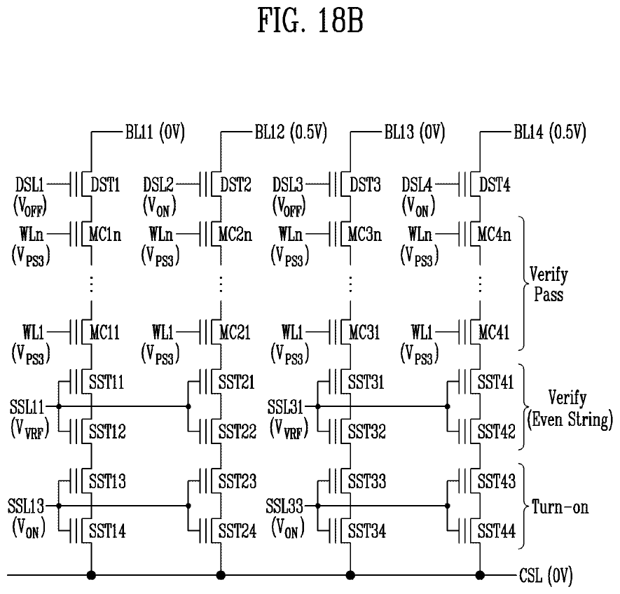

Referring to FIG. 17, step S410 of verifying the inner source select transistors included in the odd string group may include setting voltages of the common source line CSL and the bit lines (S510), applying a turn-on voltage to outer source select lines (S520), applying a turn-on voltage to a drain select line coupled to the odd string group and applying a turn-off voltage to a drain select line coupled to an even string group (S530), applying a verify pass voltage to word lines (S540), applying a verify voltage to inner source select lines (S550), and performing a sensing operation on a page buffer coupled to bit lines (S560). Step S410 will be described below with reference to FIG. 18A.

FIG. 18A is a diagram illustrating step S410 of FIG. 16. In other words, FIG. 18A illustrates a method of verifying the inner source select transistors included in the odd string group.

Referring to FIG. 18A, to verify the inner source select transistors included in the odd string group, the bit lines BL11 and BL13 coupled to the cell strings included in the odd string group may be precharged, a voltage of 0 V may be applied to the bit lines BL12 and BL14 coupled to the cell strings included in the even string group, and a voltage of 0 V may be applied to the common source line CSL at step S510. According to an embodiment, the bit lines BL11 and BL13 coupled to the cell strings included in the odd string group may be precharged to a voltage of 0.5 V. The turn on-voltage V_{ON} may be applied to the outer source select lines SSL13 and SSL33 at step S520. The turn-on voltage V_{ON} may be applied to the drain select lines DSL1 and DSL3 coupled to the odd string group, and the turn-off voltage V_{OFF} may be applied to the drain select lines DSL2 and DSL4 coupled to the even string group.

A verify pass voltage V_{PS3} may be applied to the word lines WL1 to WLn at step S540, and a verify voltage V_{VRF} may be applied to the inner source select lines SSL11 and SSL31 at step S550. A sensing operation of page buffers coupled to the odd bit lines may be performed at step S560. Therefore, a verify operation may be performed on the inner source select transistors SST11, SST12, SST31, and SST32 included in the odd string group.

FIG. 18B is a diagram illustrating step S430 of FIG. 16. FIG. 18B illustrates a method of verifying the inner source select transistors included in the even string group.

Referring to FIG. 18B, to verify the inner source select transistors included in the even string group, the bit lines BL12 and BL14 coupled to the cell strings included in the even string group may be precharged, and a voltage of 0 V may be applied to the bit lines BL11 and BL13 coupled to the cell strings included in the odd string group. The turn-on voltage V_{ON} may be applied to the drain select lines DSL2 and DSL4 coupled to the even string group, and the turn-off voltage V_{OFF} may be applied to the drain select lines DSL1 and DSL3 coupled to the odd string group. The other voltage conditions may be substantially the same as described with reference to FIG. 18A. Therefore, a verify operation may be performed on the inner source select transistors SST21, SST22, SST41, and SST42 included in the even string group.

Referring to FIGS. 16 to 18B, by the semiconductor memory device and the operating method thereof according to an embodiment of the present disclosure, a plurality of inner source select transistors may be divided into two groups, i.e., inner source select transistors included in an odd string group, and inner source select transistors included in an even string group, and a verify operation may be performed thereon. Therefore, according to the semiconductor memory device and the operating method thereof according to an embodiment, a verify operation may be performed with more accuracy, and a threshold voltage distribution width of the inner source select transistors may be narrowed.

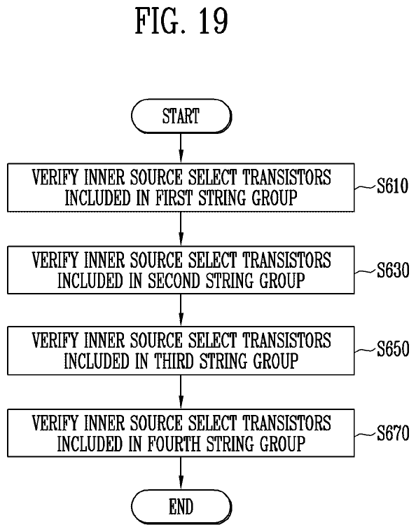

FIG. 19 is a flowchart illustrating another embodiment of step S370 shown in FIG. 13.

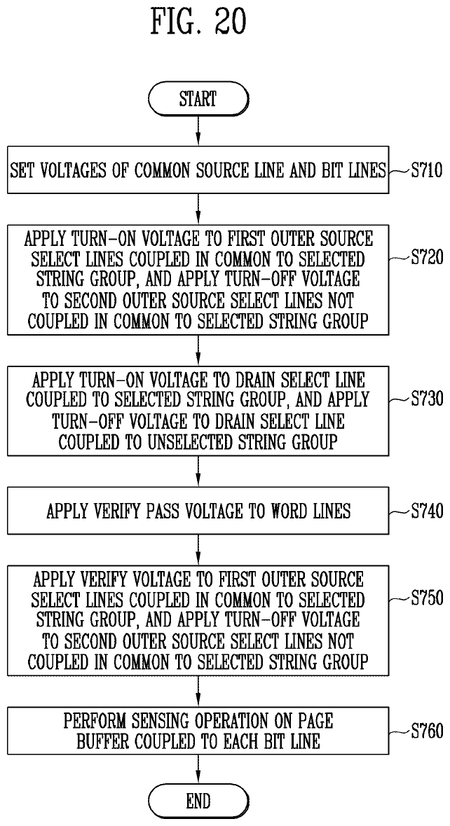

Referring to FIG. 19, inner source select transistors included in first to fourth string groups may be sequentially verified according to each string group. More specifically, the inner source select transistors included in the first string group may be verified at step S610, the inner source select transistors included in the second string group may be verified at step S630, the inner source select transistors included in the third string group may be verified at step S650, and the inner source select transistors included in the fourth string group may be verified at step S670. FIG. 19 illustrates an embodiment in which the inner source select transistors are verified according to the first to fourth string groups. However, the present disclosure is not limited thereto. In other words, the order in which the inner source select transistors are verified with respect to each of the first to fourth string groups may vary. Hereinafter, step S420 of verifying the inner source select transistors included in the first string group will be described below in more details with reference to FIG. 20.

FIG. 20 is a flowchart illustrating an embodiment of step S610 shown in FIG. 19.

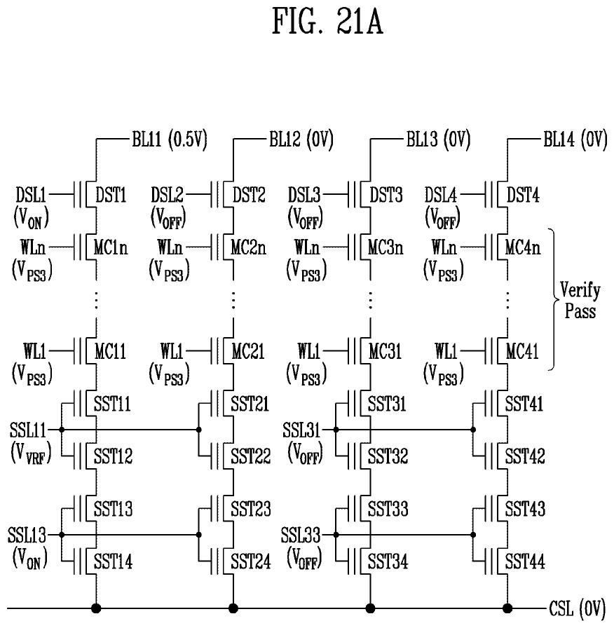

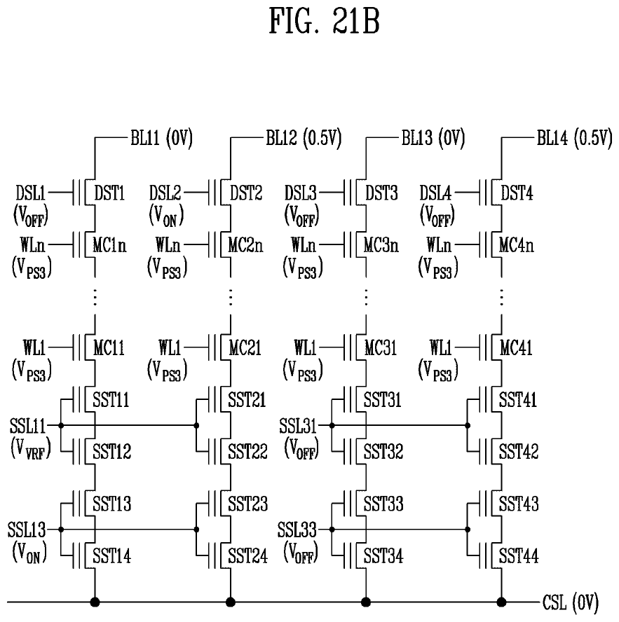

Referring to FIG. 20, step S610 of verifying the inner source select transistors included in the first string group may include setting voltages of a common source line and bit lines (step S710), applying a turn-on voltage to first outer source select lines coupled in common to a selected string group and applying a turn-off voltage to second outer source select lines not coupled in common to a selected string group (step S720), applying the turn-on voltage to a drain select line coupled to the selected string group and applying the turn-off voltage to a drain select line coupled to an unselected string group (step S730), applying a verify pass voltage to word lines (S740), applying a verify voltage to first inner source select lines coupled in common to the select string group and applying the turn-off voltage to second inner source select lines not coupled in common to the selected string group (step S750), and performing a sensing operation on a page buffer coupled to each bit line (step S760). When the steps of FIG. 20 are used as step S610 of verifying the inner source select transistors included in the first string group, the “selected string group” may be the first string group. When the steps of FIG. 20 are used as step S630 of verifying the inner source select transistors included in the second string group, the “selected string group” may be the second string group. When the steps of FIG. 20 are used as step S650 of verifying the inner source select transistors included in the third string group, the “selected string group” may be the third string group. When the steps of FIG. 20 are used as step S670 of verifying the inner source select transistors included in the fourth string group, the “selected string group” may be the fourth string group. Hereinafter, an example in which the selected string group is the first group will be described with reference to FIG. 21A.

FIG. 21A is a diagram illustrating step S610 of FIG. 19.

Referring to FIG. 21A, to verify the inner source select transistors included in the first string group, the bit line BL11 coupled to the cell strings included in the first string group may be precharged, a voltage of 0 V may be applied to the bit lines BL12, BL13, and BL14, and a voltage of 0 V may be applied to the common source line CSL at step S710. According to an embodiment, the bit line BL11 coupled to the cell strings included in the first string group may be precharged to a voltage of 0.5 V. The turn-on voltage V_{ON} may be applied to the outer source select line SSL13 coupled in common to the first string group, among the outer source select lines SSL13 and SSL33, and the turn-off voltage V_{OFF} may be applied to the outer source select line SSL33 which is not coupled in common to the first string group at step S720. The turn-on voltage V_{ON} may be applied to the drain select line DSL1 coupled to the first string group, and the turn-off voltage V_{OFF} may be applied to the drain select lines DSL2, DSL3, and DSL4 at step S730.

The verify pass voltage V_{PS3} may be applied to the word lines WL1 to WLn at step S740. The verify voltage V_{VRF} may be applied to the inner source select line SSL11 coupled in common to the first string group, and the turn-off voltage V_{OFF} may be applied to the inner source select line SSL31 not coupled in common to the first string group at step S750. A sensing operation may be performed on the page buffer coupled to the first bit line BL1 at step S760. Therefore, a verify operation may be performed on the inner source select transistors SST11 and SST12 included in the first string group.

FIG. 21B is a diagram illustrating step S630 of FIG. 19.

Referring to FIG. 21B, to verify the inner source select transistors included in the second string group, the bit line BL12 coupled to the cell strings included in the second string group may be precharged, a voltage of 0 V may be applied to the bit lines BL11, BL13, and BL14, and a voltage of 0 V may be applied to the common source line CSL. The turn-on voltage V_{ON} may be applied to the outer source select line SSL13 coupled in common to the second string group, among the outer source select lines SSL13 and SSL33, and the turn-off voltage V_{OFF} may be applied to the outer source select line SSL33 not coupled in common to the second string group. The turn-on voltage V_{ON} may be applied to the drain select line DSL2 coupled to the second string group, and the turn-off voltage V_{OFF} may be applied to the drain select lines DSL1, DSL3, and DSL4. The other voltage conditions may be substantially the same as described with reference to FIG. 21A. Therefore, a verify operation may be performed on the inner source select transistors SST21 and SST22 included in the second string group.

The method of verifying the inner source select transistors included in the first and second string groups has been described above with reference to FIGS. 21A and 21B. In the same manner, verifying the inner source select transistors included in the third and fourth string groups may be performed.

Referring to FIGS. 19 to 21B, according to the semiconductor memory device and the operating method thereof according to an embodiment of the present disclosure, the plurality of inner source select transistors may be divided into the four groups, i.e., the first to fourth string groups, and the verify operation may be performed thereon. Therefore, according to the semiconductor memory device and the operating method thereof according to an embodiment of the present disclosure, a verify operation may be performed with more accuracy, and a threshold voltage distribution width of the inner source select transistors may be narrowed.

FIG. 22 is a flowchart illustrating an embodiment of step S310 shown in FIG. 13.

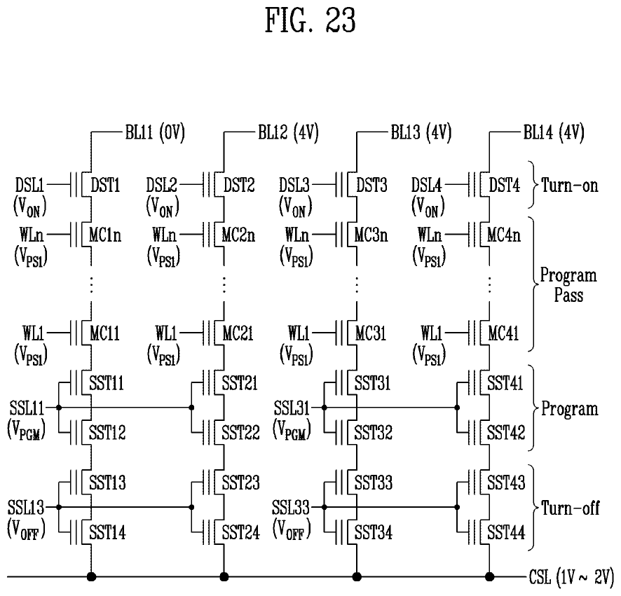

FIG. 22 illustrates an embodiment of step S310 of setting the states of the drain select lines and the bit lines in a subsequent program loop according to a verify result. More specifically, step S310 of setting the states of the drain select lines and the bit lines may include applying a program inhibition voltage to a bit line coupled to a string group which is completely verified (step 810), applying a program permission voltage to a bit line coupled to a string group which is not completely verified (step 820), and applying a turn-on voltage to drain select lines (step S830). Hereinafter, a detailed description will be made with reference to FIG. 23.

FIG. 23 is a diagram illustrating steps S810 to S830 of FIG. 22. FIG. 23 illustrates a case in which the inner source select transistors SST11 and SST12 included in the first string group are not completely verified and the inner source select transistors SST21, SST22, SST31, SST32, SST41, and SST42 are completely verified.

Referring to FIG. 23, a program inhibition voltage, e.g., a voltage of 4 V may be applied to the bit lines BL12, BL13, and BL14 coupled to the second and fourth string groups that are completely verified at step S810. A program permission voltage, e.g., a voltage of 0 V may be applied to the first bit line BL1 coupled to the first string group which is not completely verified at step S820. The turn-on voltage V_{ON} may be applied to the drain select lines DSL1, DSL2, DSL3, and DSL4. As a result, the states of the drain select lines and the bit lines may be set at step S310.

The program pass voltage V_{PS1} may be applied to the word lines at step 320, the turn-off voltage V_{OFF} may be applied to the outer source select lines SSL13 and SSL33 at step S330, and the program voltage V_{PGM} may be applied to the inner source select lines SSL11 and SSL31 at step S340. Accordingly, threshold voltages of the inner source select transistors SST11 and SST12 of the cell string coupled to the bit line BL1 to which the program permission voltage is applied may be increased, whereas threshold voltages of the remaining inner source select transistors SST21, SST22, SST31, SST32, SST41, and SST42 might not be increased.

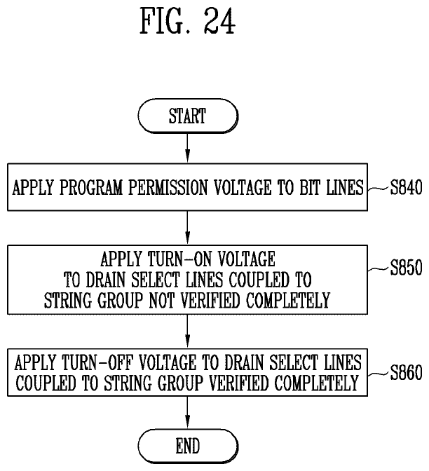

FIG. 24 is a flowchart illustrating another embodiment of step S310 shown in FIG. 13.

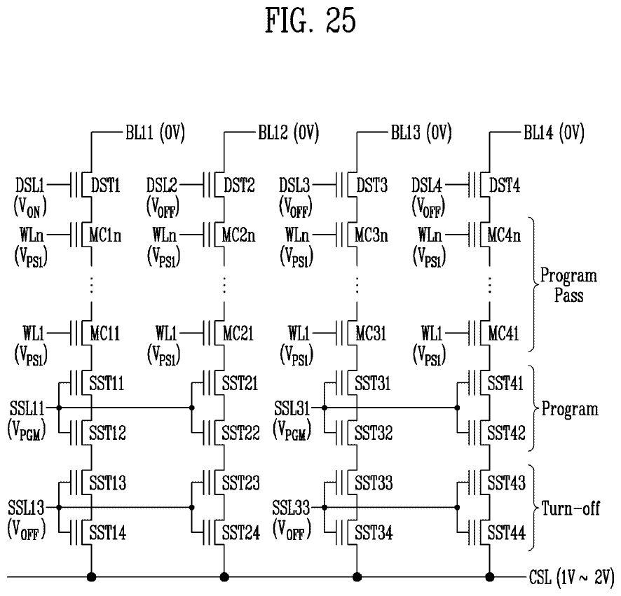

FIG. 24 illustrates another embodiment of step S310 of setting states of drain select lines and bit lines in a subsequent program loop according to a verify result of step S350. More specifically, step S310 of setting the states of the drain select lines and the bit lines may include applying a program permission voltage to bit lines (step 840), applying a turn-on voltage to the drain select lines coupled to a string group which is not completely verified (step 850), and applying a turn-off voltage to drain select lines coupled to a string group which is completely verified (step S860). Hereinafter, a detailed description will be made with reference to FIG. 25.

FIG. 25 is a diagram illustrating steps S840 to S860 of FIG. 24. FIG. 25 illustrates a case in which the inner source select transistors SST11 and SST12 included in the first string group are not completely verified and the inner source select transistors SST21, SST22, SST31, SST32, SST41, and SST42 included in the second to fourth string groups are completely verified.

Referring to FIG. 25, a program permission voltage, e.g., a voltage of 0 v may be applied to the bit lines BL11 to BL14 at step S840. The turn-on voltage V_{ON} may be applied to the drain select line DSL1 coupled to the first string group which is not completely verified at step S850. The turn-off voltage VOFF may be applied to the drain select lines DSL2, DSL3, and DSL4 coupled to the second to fourth string groups which are completely verified. As a result, the states of the drain select lines and the bit lines may be set at step S310.

The program pass voltage V_{PS1} may be applied to the word lines at step 320, the turn-off voltage V_{OFF} may be applied to the outer source select lines SSL13 and SSL33 at step S330, and the program voltage V_{PGM} may be applied to the inner source select lines SSL11 and SSL31 at step S340. Therefore, threshold voltages of the inner source select transistors SST11 and SST12 included in the first string group where the turn-on voltage V_{ON} is applied to the first drain select transistor DST1 may be increased. Threshold voltages of the inner source select transistors SST21, SST22, SST31, SST32, SST41, and SST42 included in the second to fourth string groups where the turn-off voltage VOFF is applied to the drain select transistors DST2, DST3, and DST4 may not be increased.

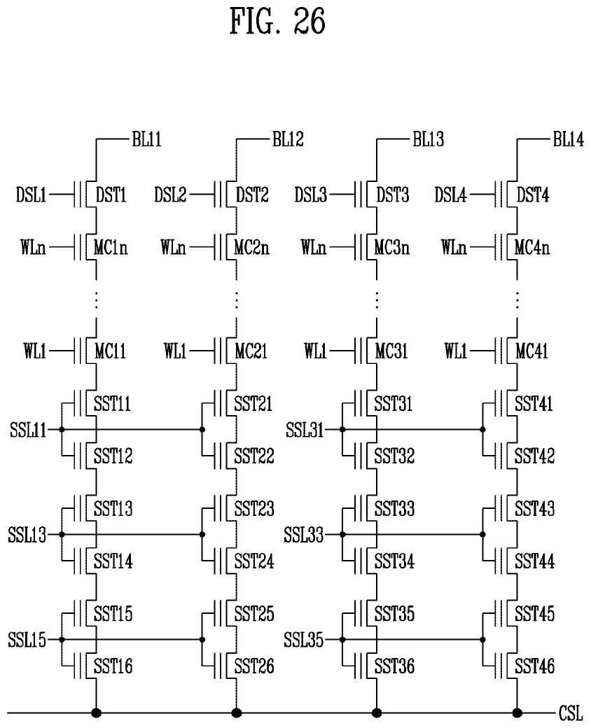

FIG. 26 is a circuit diagram illustrating another embodiment of a portion of cell strings included in first to fourth string groups.

Referring to FIG. 26, each cell string may include a plurality of source select transistors. In the circuit diagram shown in FIG. 26, the first cell string may include first to sixth source select transistors SST11 to SST16, and the second cell string may include first to sixth source select transistors SST21 to SST26. The third cell string may include first to sixth source select transistors SST31 to SST36, and the fourth cell string may include first to sixth source select transistors SST41 to SST46.

As described above, source select transistors located adjacent to memory cells, among a plurality of source select transistors, may be referred to as “inner source select transistors,” and source select transistors located adjacent to the common source line CSL, among the plurality of source select transistors, may be referred to as “outer source select transistors.” In addition, in the present disclosure, source select transistors located between the inner source select transistors and the outer source select transistors, among the plurality of source select transistors, may be referred to as “intermediate source select transistors.”

For example, the inner source select transistors, among the source select transistors SST11 to SST16 of the first cell string, may be the first and second source select transistors SST11 and SST12, the intermediate source select transistors may be the third and fourth source select transistors SST13 and SST14, and the outer source select transistors may be the fifth and sixth source select transistors SST15 and SST16. In the same manner, the inner source select transistors, among the source select transistors SST21 to SST26 of the second cell string, may be the first and second source select transistors SST21 and SST22, the intermediate source select transistors may be the third and fourth source select transistors SST23 and SST24, and the outer source select transistors may be the fifth and sixth source select transistors SST25 and SST26. In addition, the inner source select transistors, among the source select transistors SST31 to SST36 of the third cell string, may be the first and second source select transistors SST31 and SST32, the intermediate source select transistors may be the third and fourth source select transistors SST33 and SST34, and the outer source select transistors may be the fifth and sixth source select transistors SST35 and SST36. Lastly, the inner source select transistors, among the source select transistors SST41 to SST46 of the fourth cell string, may be the first and second source select transistors SST41 and SST42, the intermediate source select transistors may be the third and fourth source select transistors SST43 and SST44, and the outer source select transistors may be the fifth and sixth source select transistors SST45 and SST46.

In the present disclosure, a source select line coupled to the intermediate source select transistor is referred to as an “intermediate source select line.” As shown in FIG. 26, the first source select lines SSL11 and SSL31 coupled to the first to fourth cell strings may be inner source select lines, the third source select lines SSL13 and SSL33 may be intermediate source select lines, and the fifth source select lines SSL15 and SSL35 may be outer source select lines.

Because the intermediate source select lines coupled to the intermediate source select transistors are provided separately from the outer source select lines and the inner source select lines, the intermediate source select transistors may operate independently of the outer source select transistors and the inner source select transistors.

According to an embodiment of the present disclosure, during a program operation of the source select transistors, the intermediate source select transistors may be programmed together with the outer source select transistors.

In other words, referring to the flowchart shown in FIG. 10, the intermediate source select transistors may be programmed together with the outer source select transistors at step S110. In the same manner as the outer source select transistors, the intermediate source select transistors may be programmed with a verify operation. The intermediate source select transistors may be programmed by applying a program voltage to the intermediate source select lines a predetermined number of times.

According to another embodiment of the present disclosure, during a program operation of the source select transistors, the intermediate source select transistors may be programmed together with the inner source select transistors.

In other words, referring to the flowchart shown in FIG. 10, the intermediate source select transistors may be programmed together with the outer source select transistors at step S130. In the same manner as the inner source select transistors, a program operation may be performed together with the verify operation on the intermediate source select transistors. According to an embodiment, intermediate source select transistors may be programmed using an ISPP method. According to another embodiment, by repetitively applying a program voltage with a single level to gates of intermediate source select transistors, the intermediate source select transistors may be programmed.

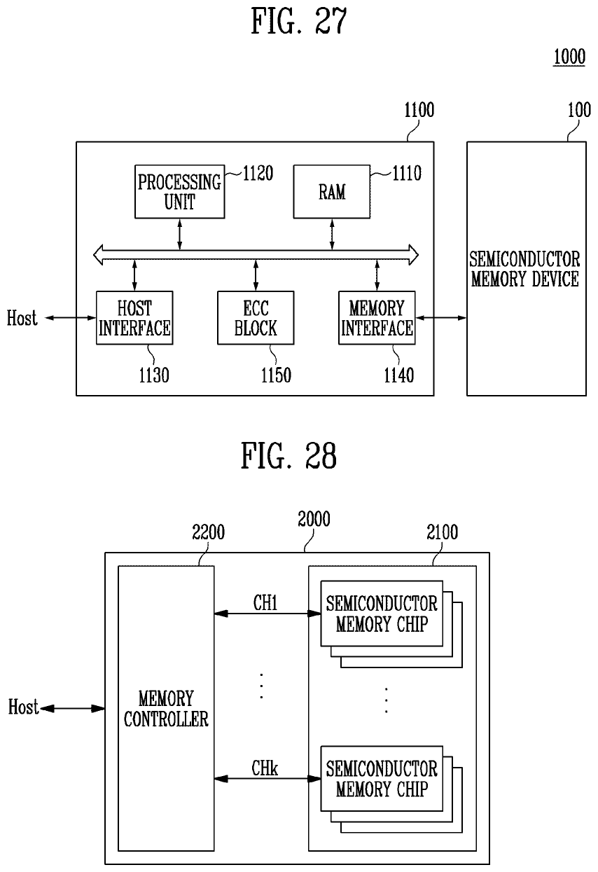

FIG. 27 is a diagram illustrating an embodiment of a memory system 1000 including the semiconductor memory device 100 of FIG. 1.

Referring to FIG. 27, the memory system 1000 may include the semiconductor memory device 100 and a memory controller 1100. The semiconductor memory device 100 may be the semiconductor memory device which is described above with reference to FIG. 1.

The memory controller 1100 may be coupled to a host and the semiconductor memory device 100. In response to a request from the host, the memory controller 1100 may access the semiconductor memory device 100. For example, the memory controller 1100 may control write, read, erase, and background operations of the semiconductor memory device 100. The memory controller 1100 may provide an interface between the semiconductor memory device 100 and the host. The memory controller 1100 may drive firmware for controlling the semiconductor memory device 100.

The memory controller 1100 may include random access memory (RAM) 1110, a processing unit 1120, a host interface 1130, a memory interface 1140, and an error correction code (ECC) block 1150. The RAM 1110 may serve as at least one of working memory, cache memory between the semiconductor memory device 100 and the host, and buffer memory between the semiconductor memory device 100 and the host. The processing unit 1120 may control overall operations of the memory controller 1100. In addition, the memory controller 1100 may temporarily store program data provided from the host during a write operation.

The host interface 1130 may include a protocol for exchanging data between the host and the memory controller 1100. According to an embodiment, the memory controller 1100 may communicate with the host through one or more various protocols such as a universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer system interface (SCSI) protocol, an enhanced small disk interface (ESDI) protocol, an integrated drive electronics (IDE) protocol, a private protocol, etc.

The memory interface 1140 may interface with the semiconductor memory device 100. For example, the memory interface 1140 may include a NAND interface or a NOR interface.

The ECC block 1150 may be configured to detect and correct an error in data received from the semiconductor memory device 100. The processing unit 1120 may control the semiconductor memory device 100 to control a read voltage according to an error detection result and perform re-read. According to an embodiment, the ECC block 1150 may be provided as a component of the memory controller 1100.

The memory controller 1100 and the semiconductor memory device 100 may be integrated into a single semiconductor device to form a memory card. For example, the memory controller 1100 and the semiconductor memory device 100 may be integrated into a single semiconductor device and form a memory card, such as a personal computer memory card international association (PCMCIA), a compact flash (CF) card, a smart media card (SM or SMC), a memory stick multimedia card (MMC, RS-MMC, or MMCmicro), an SD card (SD, miniSD, microSD, or SDHC), a universal flash storage (UFS), and the like.

The memory controller 1100 and the semiconductor memory device 100 may be integrated into a single semiconductor device to form a solid state drive (SSD). The SSD may include storage device that is configured to store data in a semiconductor memory. When the memory system 1000 serves as the SSD, an operating speed of the host coupled to the memory system 1000 may be remarkably improved.

In another example, the memory system 1000 may be provided as one of various elements of an electronic device such as a computer, an ultra mobile PC (UMPC), a workstation, a net-book, a personal digital assistant (PDA), a portable computer, a web tablet, a wireless phone, a mobile phone, a smart phone, an e-book, a portable multimedia player (PMP), a game console, a navigation device, a black box, a digital camera, a 3-dimensional television, a digital audio recorder, a digital audio player, a digital picture recorder, a digital picture player, a digital video recorder, a digital video player, a device capable of transmitting/receiving information in an wireless environment, one of various devices for forming a home network, one of various electronic devices for forming a computer network, one of various electronic devices for forming a telematics network, an RFID device, or the like.

In an embodiment, the semiconductor memory device 100 or the memory system 1000 may be mounted in packages in various forms. For example, the semiconductor memory device 100 or the memory system 1000 may be embedded in packages such as a package on package (PoP), ball grid arrays (BGAs), chip scale packages (CSPs), a plastic leaded chip carrier (PLCC), a plastic dual in line package (PDIP), a die in waffle pack, a die in wafer form, a chip on board (COB), a ceramic dual in line package (CERDIP), a plastic metric quad flat pack (MQFP), a thin quad flatpack (TQFP), a small outline integrated circuit (SOIC) package, a shrink small outline package (SSOP), a thin small outline package (TSOP), a system in package (SIP), a multichip package (MCP), a wafer-level fabricated package (WFP), a wafer-level processed stack package (WSP), or the like.

FIG. 28 is a block diagram illustrating an application example of the memory system 1000 of FIG. 27.

Referring to FIG. 28, a memory system 2000 may include a semiconductor memory device 2100 and a memory controller 2200. The semiconductor memory device 2100 may include semiconductor memory chips. The semiconductor memory chips may be divided into a plurality of groups.

FIG. 28 illustrates the groups communicating with the memory controller 2200 through first to k-th channels CH1 to CHk. Each of the semiconductor memory chips may be configured and operated in substantially the same manner as the semiconductor memory device 100 described above with reference to FIG. 1.

Each group of semiconductor memory chips may communicate with the memory controller 2200 through a single common channel. The memory controller 2200 may be configured in substantially the same manner as the memory controller 1100 described with reference to FIG. 27, and configured to control the plurality of memory chips of the semiconductor memory device 2100 through the plurality of channels CH1 to CHk.

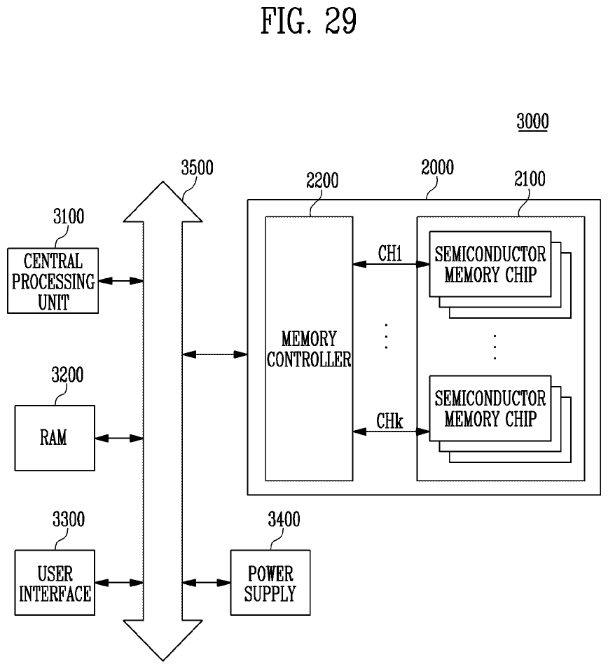

FIG. 29 is a block diagram illustrating a computing system 3000 including the memory system 2000 described above with reference to FIG. 28.

The computing system 3000 may include a central processing unit 3100, random access memory (RAM) 3200, a user interface 3300, a power supply 3400, a system bus 3500, and the memory system 2000.

The memory system 2000 may be electrically connected to the central processing unit 3100, the RAM 3200, the user interface 3300 and the power supply 3400 through the system bus 3500. Data provided trough the user interface 3300 or processed by the central processing unit 3100 may be stored in the memory system 2000.

In an embodiment, the semiconductor memory device 2100 may be coupled to the system bus 3500 through the memory controller 2200. In another embodiment, the semiconductor memory device 2100 may be directly coupled to the system bus 3500. The central processing unit 3100 and the RAM 3200 may perform functions of the memory controller 2200.

As illustrated in FIG. 29, the memory system 2000 shown in FIG. 28 may be provided. However, the memory system 2000 may be replaced by the memory system 1000 shown in FIG. 27. According to an embodiment, the computing system 3000 may include both of the memory systems 1000 and 2000 described above with reference to FIGS. 27 and 28.

According to the present disclosure, a semiconductor memory device improving a threshold voltage distribution of select transistors and an operating method thereof may be provided.

What is claimed is:

1. A semiconductor memory device, comprising:
a memory block including a plurality of string groups;
a peripheral circuit configured to perform a program operation on source select transistors included in the memory block; and
control logic capable of controlling the program operation of the peripheral circuit,
wherein each of the plurality of string groups includes at least one cell string, and the at least one cell string includes inner source select transistors located adjacent to memory cells and outer source select transistors located adjacent to a common source line,
wherein the control logic is capable of controlling the peripheral circuit to perform a program operation on the outer source select transistors and a program operation on the inner source select transistors by applying a program voltage a plurality of times to an inner source select line coupled to the inner source select transistors, and
wherein the control logic is capable of controlling the peripheral circuit to perform a verify operation by dividing the inner source select transistors into at least two groups during the program operation of the inner source select transistors.

2. The semiconductor memory device of claim 1, wherein the plurality of string groups include first, second, third, and fourth string groups,
wherein an inner source select transistor in the first string group and an inner source select transistor in the second string group are commonly coupled to a first inner source select line,
wherein an inner source select transistor in the third string group and an inner source select transistor in the fourth string group are commonly coupled to a second inner source select line,
wherein an outer source select transistor in the first string group and an outer source select transistor in the second string group are commonly coupled to a first outer source select line, and
wherein an outer source select transistor in the third string group and an outer source select transistor in the fourth string group are commonly coupled to a second outer source select line.

3. The semiconductor memory device of claim 2, wherein the control logic is capable of, during the program operation of the outer source select transistors:
controlling the peripheral circuit to apply a turn-on voltage to first to fourth drain select lines coupled to the first to fourth string groups, respectively, and to apply a program pass voltage to the first and second inner source select lines and word lines coupled to the first to fourth string groups; and
controlling the peripheral circuit to apply the program voltage to the first and second outer source select lines.

4. The semiconductor memory device of claim 3, wherein the control logic is capable of controlling the peripheral circuit to apply the program voltage to the first and second outer source select lines a predetermined number of times.

5. The semiconductor memory device of claim 2, wherein the control logic is capable of, during the program operation of the outer source select transistors:
controlling the peripheral circuit to apply a turn-on voltage to first to fourth drain select lines coupled to the first to fourth string groups, respectively, and to apply a program pass voltage to word lines coupled to the first to fourth string groups; and
controlling the peripheral circuit to apply the program voltage to the first and second outer source select lines and the first and second inner source select lines.

6. The semiconductor memory device of claim 5, wherein the control logic is capable of controlling the peripheral circuit to apply the program voltage to the first and second outer source select lines and the first and second inner source select lines a predetermined number of times.

7. The semiconductor memory device of claim 2, wherein the program operation of the inner source select transistors includes a plurality of program loops, and the control logic is capable of, during at least one of the plurality of program loops:
setting states of first to fourth drain select lines and first to fourth bit lines coupled to the first to fourth string groups, respectively;
applying a program pass voltage to word lines coupled to the first to fourth string groups;
applying a turn-off voltage to the first and second outer source select lines;
applying the program voltage to the first and second inner source select lines; and
performing the verify operation on the inner source select transistors included in the first to fourth string groups.

8. The semiconductor memory device of claim 7, wherein the control logic is capable of controlling, during the verify operation of the inner source select transistors included in the first to fourth string groups, the peripheral circuit to:
verify the inner source select transistors included in the first and third string groups, among the first to fourth string groups; and
verify the inner source select transistors included in the second and fourth string groups, among the first to fourth string groups.

9. The semiconductor memory device of claim 8, wherein the control logic is capable of controlling, during the verify operation of the inner source select transistors included in the first to third string groups, the peripheral circuit to:
set a voltage of the common source line and a voltage of bit lines coupled to the first to fourth string groups;
apply a turn-on voltage to the first and second outer source select lines;
apply the turn-on voltage to drain select lines coupled to the first and third string groups and the turn-off voltage to drain select lines coupled to the second and fourth string groups;
apply a verify pass voltage to the word lines; and
apply a verify voltage to the first and second inner source select lines.

10. The semiconductor memory device of claim 9, wherein to set the voltage of the common source line and the voltage of the bit lines coupled to the first to fourth string groups, the control logic is capable of controlling the peripheral circuit to:
apply a ground voltage to the common source line;
apply a first voltage greater than the ground voltage to the bit lines coupled to the first to third string groups; and
apply the ground voltage to the bit lines coupled to the second and fourth string groups.

11. The semiconductor memory device of claim 7, wherein the control logic is capable of controlling, during the verify operation of the inner source select transistors included in the first to fourth string groups, the peripheral circuit to:
verify the inner source select transistors included in the first string group, among the first to fourth string groups;
verify the inner source select transistors included in the second string group, among the first to fourth string groups;
verify the inner source select transistors included in the third string group, among the first to fourth string groups; and
verify the inner source select transistors included in the fourth string group, among the first to fourth string groups.

12. The semiconductor memory device of claim 11, wherein the control logic is capable of controlling, during the verify operation of the inner source select transistors included in the first string group, the peripheral circuit to:
set a voltage of the common source line and a voltage of bit lines coupled to the first to fourth string groups;
apply a turn-on voltage to the first outer source select line and the turn-off voltage to the second outer source select line;
apply the turn-on voltage to a drain select line coupled to the first string group and the turn-off voltage to drain select lines coupled to the second to fourth string groups;
apply a verify pass voltage to the word lines; and
apply a verify voltage to the first inner source select line and the turn-off voltage to the second inner source select line.

13. The semiconductor memory device of claim 7, wherein to set the states of the first to fourth drain select lines and the first to fourth bit lines coupled to the first to fourth string groups, respectively, the control logic is capable of controlling the peripheral circuit to:
apply a program inhibition voltage to a bit line coupled to a string group verified completely in a previous program loop;
apply a program permission voltage to a bit line coupled to a string group not verified completely in the previous program loop; and
apply a turn-on voltage to drain select lines coupled to the first to fourth string groups.

14. The semiconductor memory device of claim 7, wherein to set the states of the first to fourth drain select lines and the first to fourth bit lines coupled to the first to fourth string groups, respectively, the control logic is capable of controlling the peripheral circuit to:
apply a program permission voltage to bit lines coupled to the first to fourth string groups;
apply a turn-on voltage to a drain select line coupled to a string group not verified completely in a previous program loop; and
apply the turn-off voltage to a bit line coupled to a string group completely verified in the previous program loop.

15. The semiconductor memory device of claim 7, wherein the control logic is capable of controlling the peripheral circuit to perform a soft erase operation on the outer source select transistors included in the first to fourth string groups in response to verify completion of the inner source select transistors of all string groups.

16. A method of operating a semiconductor memory device performing a program operation on a source select transistor of a memory block including a plurality of string groups, the plurality of string groups each including at least one cell string, the at least one cell string including inner source select transistors located adjacent to memory cells and outer source select transistors located adjacent to a common source line, the method comprising:
performing a program operation on the outer source select transistors; and
performing a program operation on the inner source select transistors by applying a plurality of program voltages to gates of the inner source select transistors a plurality of times,
wherein the performing of the program operation on the inner source select transistors comprises performing a verify operation by dividing the inner source select transistors into at least two groups.

17. The method of claim 16, wherein the plurality of string groups include first, second, third, and fourth string groups,
wherein an inner source select transistor in the first string group and an inner source select transistor in the second string group are commonly coupled to a first inner source select line,
wherein an inner source select transistor in the third string group and an inner source select transistor in the fourth string group are commonly coupled to a second inner source select line,
wherein an outer source select transistor in the first string group and an outer source select transistor in the second string group are commonly coupled to a first outer source select line,
wherein an outer source select transistor in the third string group and an outer source select transistor in the fourth string group are commonly coupled to a second outer source select line, and
wherein performing the program operation on the outer source select transistors comprises:
applying a turn-on voltage to first to fourth drain select lines coupled to the first to fourth string groups, respectively, and applying a program pass voltage to the first and second inner source select lines and word lines coupled to the first to fourth string groups; and
applying a program voltage to the first and second outer source select lines.

18. The method of claim 17, wherein applying the program voltage to the first and second outer source select lines comprises applying the program voltage to the first and second source select lines a predetermined number of times.

19. The method of claim 16, wherein the plurality of string groups includes first, second, third, and fourth string groups,
wherein an inner source select transistor in the first string group and an inner source select transistor in the second string group are commonly coupled to a first inner source select line,
wherein an inner source select transistor in the third string group and an inner source select transistor in the fourth string group are commonly coupled to a second inner source select line,
wherein an outer source select transistor in the first string group and an outer source select transistor in the second string group are commonly coupled to a first outer source select line,
wherein an outer source select transistor in the third string group and an outer source select transistor in the fourth string group are commonly coupled to a second outer source select line, and
wherein performing the program operation on the outer source select transistors comprises:
applying a turn-on voltage to first to fourth drain select lines coupled to the first to fourth string groups, respectively, and applying a program pass voltage to word lines coupled to the first to fourth string groups; and
applying a program voltage to the first and second outer source select lines and the first and second inner source select lines.

20. The method of claim 19, wherein applying the program voltage to the first and second inner source select lines and the first and second outer source select lines comprises applying the program voltage to the first and second inner source select lines and the first and second outer source select lines a predetermined number of times.

21. The method of claim 16, wherein performing the program operation on the inner source select transistors comprises a plurality of program loops, and one of the plurality of program loops comprises:
setting states of first to fourth drain select lines and first to fourth bit lines coupled to the first to fourth string groups, respectively;
applying a program pass voltage to word lines coupled to the first to fourth string groups;
applying a turn-off voltage to the first and second outer source select lines;
applying a program voltage to the first and second inner source select lines; and
performing the verify operation on the inner source select transistors included in the first to fourth string groups.

22. The method of claim 21, wherein performing the verify operation on the inner source select transistors included in the first to fourth string groups comprises:
verifying the inner source select transistors included in the first and third string groups, among the first to fourth string groups; and
verifying the inner source select transistors included in the second and fourth string groups, among the first to fourth string groups.

23. The method of claim 22, wherein performing the verify operation on the inner source select transistors included in the first to third string groups comprises:
setting a voltage of the common source line and a voltage of bit lines coupled to the first to fourth string groups;
applying a turn-on voltage to the first and second outer source select lines;
applying the turn-on voltage to drain select lines coupled to the first and third string groups and the turn-off voltage to drain select lines coupled to the second and fourth string groups;
applying a verify pass voltage to the word lines; and
applying a verify voltage to the first and second inner source select lines.

24. The method of claim 23, wherein setting the voltage of the common source line and the voltage of the bit lines coupled to the first to fourth string groups comprises:
applying a ground voltage to the common source line;
applying a first voltage greater than the ground voltage to the bit lines coupled to the first to third string groups; and
applying the ground voltage to the bit lines coupled to the second and fourth string groups.

25. The method of claim 21, wherein performing the verify operation on the inner source select transistors included in the first to fourth string groups comprises:
verifying the inner source select transistors included in the first string group, among the first to fourth string groups;
verifying the inner source select transistors included in the second string group, among the first to fourth string groups;
verifying the inner source select transistors included in the third string group, among the first to fourth string groups; and
verifying the inner source select transistors included in the fourth string group, among the first to fourth string groups.

26. The method of claim 25, wherein performing the verify operation of the inner source select transistors included in the first string group comprises:
setting a voltage of the common source line and a voltage of bit lines coupled to the first to fourth string groups;
applying a turn-on voltage to the first outer source select line and the turn-off voltage to the second outer source select line;
applying the turn-on voltage to a drain select line coupled to the first string group and the turn-off voltage to drain select lines coupled to the second to fourth string groups;
applying a verify pass voltage to the word lines; and
applying a verify voltage to the first inner source select line and the turn-off voltage to the second inner source select line.

27. The method of claim 21, wherein setting the states of the first to fourth drain select lines and the first to fourth bit lines coupled to the first to fourth string groups, respectively, comprises:
applying a program inhibition voltage to a bit line coupled to a string group verified completely in a previous program loop;
applying a program permission voltage to a bit line coupled to a string group not verified completely in the previous program loop; and
applying a turn-on voltage to drain select lines coupled to the first to fourth string groups.

28. The method of claim 21, wherein setting the states of the first to fourth drain select lines and the first to fourth bit lines coupled to the first to fourth string groups, respectively, comprises:
applying a program permission voltage to bit lines coupled to the first to fourth string groups;
applying a turn-on voltage to a drain select line coupled to a string group not verified completely in a previous program loop; and
applying the turn-off voltage to a bit line coupled to a string group verified completely in the previous program loop.

29. The method of claim 21, further comprising performing a soft erase operation on the outer source select transistors included in the first to fourth string groups when verification of the inner source select transistors of all string groups is completed.
